(19) United States
(12) Patent Application Publication
(10) Pub. No.: US 2025/0016976 A1
(43) Pub. Date: Jan. 9, 2025

(54) SEMICONDUCTOR MEMORY DEVICE

(71) Applicant: Kioxia Corporation, Tokyo (JP)

(72) Inventors: Teruhisa SONOHARA, Yokkaichi Mie (JP); Shunichi SENO, Yokkaichi Mie (JP); Hiroki TOKUHIRA, Kawasaki Kanagawa (JP); Fumitaka ARAI, Yokkaichi Mie (JP)

(73) Assignee: Kioxia Corporation, Tokyo (JP)

(21) Appl. No.: 18/887,835

(22) Filed: Sep. 17, 2024

Related U.S. Application Data
(63) Continuation of application No. 18/458,054, filed on Aug. 29, 2023, now Pat. No. 12,127,391.
Application No. 18/458,054 is a division of application No. 17/472,902, filed on Sep. 13, 2021, now Pat. No. 11,778,808.

(30) Foreign Application Priority Data
Apr. 5, 2021 (JP) 2021-064476

(51) Int. Cl. H10B 12/00; G11C 11/406; G11C 11/4076; G11C 11/4096; H01L 21/02; H01L 29/66; H01L 29/786

(52) U.S. Cl. CPC H10B 12/30; G11C 11/40615; G11C 11/4076; G11C 11/4096; H01L 21/02565; H01L 29/66969; H01L 29/7869; H10B 12/03; H10B 12/05

(57) ABSTRACT

A semiconductor memory device includes: a first wiring; a first semiconductor layer connected to the first wiring, the first semiconductor layer; a first electrode, the first electrode being connected to the first semiconductor layer; a second electrode disposed between the first electrode and the first wiring, the second electrode being opposed to the first semiconductor layer; a third electrode disposed between the second electrode and the first wiring, the third electrode; a second semiconductor layer disposed between the third electrode and the first semiconductor layer, the second semiconductor layer being opposed to the third electrode; and an electric charge accumulating layer electrically connected to the first wiring via the second semiconductor layer, the electric charge accumulating layer being opposed to the first semiconductor layer.

### CROSS-REFERENCE TO RELATED APPLICATIONS

This application is a continuation of U.S. patent application Ser. No. 18/458,054, filed Aug. 29, 2023, which is division of U.S. patent application Ser. No. 17/472,902, filed on Sep. 13, 2021, which is based upon and claims the benefit of Japanese Patent Application No. 2021-064476, filed on Apr. 5, 2021, the entire contents of which are incorporated herein by reference.

### BACKGROUND

### Field

Embodiments described herein relate generally to a semiconductor memory device.

### Description of the Related Art

There has been known a semiconductor memory device where a plurality of memory cells are stacked in a direction intersecting with a surface of a substrate.

### BRIEF DESCRIPTION OF THE DRAWINGS

FIG. 1 is a schematic perspective view illustrating a part of a configuration of a semiconductor memory device according to a first embodiment;

FIG. 2 is a schematic plan view illustrating a part of the configuration of the semiconductor memory device according to the embodiment;

FIG. 3 is a schematic circuit diagram illustrating a part of the configuration of the semiconductor memory device according to the embodiment;

FIG. 4 is a schematic cross-sectional view for describing a manufacturing method of the semiconductor memory device according to the first embodiment;

FIG. 5 is a schematic cross-sectional for describing the manufacturing method;

FIG. 6 is a schematic cross-sectional for describing the manufacturing method;

FIG. 7 is a schematic cross-sectional for describing the manufacturing method;

FIG. 8 is a schematic cross-sectional for describing the manufacturing method;

FIG. 9 is a schematic cross-sectional for describing the manufacturing method;

FIG. 10 is a schematic cross-sectional for describing the manufacturing method;

FIG. 11 is a schematic cross-sectional for describing the manufacturing method;

FIG. 12 is a schematic cross-sectional for describing the manufacturing method;

FIG. 13 is a schematic cross-sectional for describing the manufacturing method;

FIG. 14 is a schematic cross-sectional for describing the manufacturing method;

FIG. 15 is a schematic cross-sectional for describing the manufacturing method;

FIG. 16 is a schematic cross-sectional for describing the manufacturing method;

FIG. 17 is a schematic cross-sectional for describing the manufacturing method;

FIG. 18 is a schematic cross-sectional for describing the manufacturing method;

FIG. 19 is a schematic cross-sectional for describing the manufacturing method;

FIG. 20 is a schematic cross-sectional for describing the manufacturing method;

FIG. 21 is a schematic cross-sectional for describing the manufacturing method;

FIG. 22 is a schematic cross-sectional for describing the manufacturing method;

FIG. 23 is a schematic cross-sectional for describing the manufacturing method;

FIG. 24 is a schematic cross-sectional for describing the manufacturing method;

FIG. 25 is a schematic cross-sectional for describing the manufacturing method;

FIG. 26 is a schematic cross-sectional for describing the manufacturing method;

FIG. 27 is a schematic cross-sectional for describing the manufacturing method;

FIG. 28 is a schematic cross-sectional for describing the manufacturing method;

FIG. 29 is a schematic cross-sectional for describing the manufacturing method;

FIG. 30 is a schematic cross-sectional for describing the manufacturing method;

FIG. 31 is a schematic cross-sectional for describing the manufacturing method;

FIG. 32 is a schematic cross-sectional for describing the manufacturing method;

FIG. 33 is a schematic cross-sectional for describing the manufacturing method;

FIG. 34 is a schematic cross-sectional for describing the manufacturing method;

FIG. 35 is a schematic cross-sectional for describing the manufacturing method;

FIG. 36 is a schematic cross-sectional for describing the manufacturing method;

FIG. 37 is a schematic cross-sectional for describing the manufacturing method;

FIG. 38 is a schematic cross-sectional for describing the manufacturing method;

FIG. 39 is a schematic cross-sectional for describing the manufacturing method;

FIG. 40 is a schematic cross-sectional for describing the manufacturing method;

FIG. 41 is a schematic circuit diagram for describing a read operation of the semiconductor memory device according to the first embodiment;

FIG. 42 is a schematic circuit diagram for describing a write operation of the semiconductor memory device according to the first embodiment;

FIG. 43 is a schematic waveform diagram for describing a data inversion operation of the semiconductor memory device according to the first embodiment;

FIG. 44 is a schematic circuit diagram for describing the data inversion operation;

FIG. 45 is a schematic circuit diagram for describing the data inversion operation;

FIG. 46 is a schematic circuit diagram for describing the data inversion operation;

FIG. 47 is a schematic waveform diagram for describing a self-refresh operation of the semiconductor memory device according to the first embodiment

FIG. 48 is a schematic circuit diagram for describing the self-refresh operation;

FIG. 49 is a schematic circuit diagram for describing the self-refresh operation;

FIG. 50 is a schematic circuit diagram for describing the self-refresh operation;

FIG. 51 is a schematic plan view illustrating a part of a configuration of a semiconductor memory device according to a second embodiment;

FIG. 52 is a schematic circuit diagram illustrating a part of the configuration of the semiconductor memory device;

FIG. 53 is a schematic circuit diagram for describing a read operation of the semiconductor memory device according to the second embodiment;

FIG. 54 is a schematic circuit diagram for describing a write operation of the semiconductor memory device according to the second embodiment;

FIG. 55 is a schematic plan view illustrating a part of a configuration of a semiconductor memory device according to a third embodiment;

FIG. 56 is a schematic circuit diagram illustrating a part of the configuration of the semiconductor memory device;

FIG. 57 is a schematic circuit diagram for describing a read operation of the semiconductor memory device according to the third embodiment;

FIG. 58 is a schematic plan view illustrating a part of a configuration of a semiconductor memory device according to a fourth embodiment;

FIG. 59 is a schematic circuit diagram illustrating a part of the configuration of the semiconductor memory device;

FIG. 60 is a schematic plan view illustrating a part of a configuration of a semiconductor memory device according to a fifth embodiment;

FIG. 61 is a schematic plan view for describing a read operation of the semiconductor memory device according to the fifth embodiment;

FIG. 62 is a schematic energy band diagram for describing the read operation;

FIG. 63 is a schematic energy band diagram for describing the read operation;

FIG. 64 is a schematic plan view for describing a write operation of the semiconductor memory device according to the fifth embodiment;

FIG. 65 is a schematic plan view illustrating a part of a configuration of a semiconductor memory device according to a sixth embodiment;

FIG. 66 is a schematic circuit diagram illustrating a part of the configuration of the semiconductor memory device;

FIG. 67 is a schematic circuit diagram for describing a read operation of the semiconductor memory device according to the sixth embodiment; and

FIG. 68 is a schematic circuit diagram for describing a write operation of the semiconductor memory device according to the sixth embodiment.

### DETAILED DESCRIPTION

A semiconductor memory device according to one embodiment comprises: a first wiring extending in a first direction; a first semiconductor layer connected to the first wiring, the first semiconductor layer extending in a second direction intersecting with the first direction; a first electrode extending in a third direction intersecting with the first direction and the second direction, the first electrode being connected to the first semiconductor layer; a second electrode disposed between the first electrode and the first wiring, the second electrode extending in the third direction and being opposed to the first semiconductor layer; a third electrode disposed between the second electrode and the first wiring, the third electrode extending in the third direction; a second semiconductor layer disposed between the third electrode and the first semiconductor layer, the second semiconductor layer being opposed to the third electrode; and an electric charge accumulating layer electrically connected to the first wiring via the second semiconductor layer, the electric charge accumulating layer being opposed to the first semiconductor layer.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when referring to that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, when referring to that the first configuration “is connected between” the second configuration and a third configuration, it may mean that the first configuration, the second configuration, and the third configuration are connected in series and the second configuration is connected to the third configuration via the first configuration.

In this specification, when referring to that a circuit or the like “electrically conducts” two wirings or the like, it may mean, for example, that this circuit or the like includes a transistor or the like, this transistor or the like is disposed on a current path between the two wirings, and this transistor or the like is turned ON.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

### First Embodiment

### [Configuration]

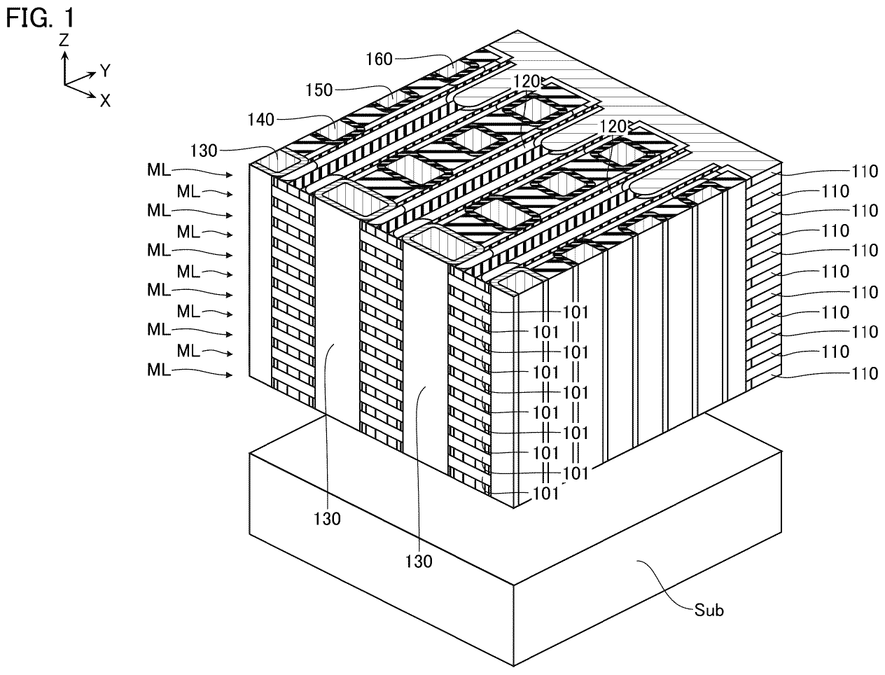

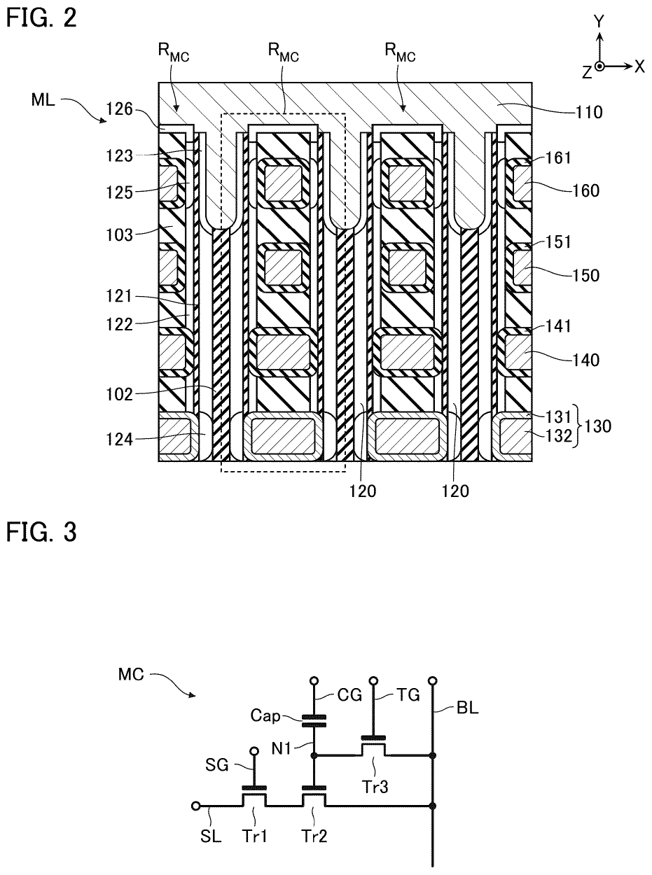

FIG. 1 is a schematic perspective view illustrating a part of a configuration of a semiconductor memory device according to the first embodiment. FIG. 2 is a schematic plan view illustrating a part of the configuration of the semiconductor memory device according to the embodiment. FIG. 3 is a schematic circuit diagram illustrating a part of the configuration of the semiconductor memory device according to the embodiment.

As illustrated in FIG. 1, the semiconductor memory device according to the embodiment includes a semiconductor substrate Sub. The semiconductor substrate Sub is, for example, a semiconductor substrate of silicon (Si) containing P-type impurities such a boron (B), or the like. The semiconductor memory device according to the embodiment includes a plurality of memory layers ML arranged in a Z direction. Between two memory layers ML mutually adjacent in the Z direction, an insulating layer 101 of silicon oxide (SiO₂) or the like is disposed.

As illustrated in FIG. 2, the memory layer ML includes a plurality of memory cell regions R_{MC} arranged in an X direction and a conductive layer 110 extending in the X direction along the plurality of memory cell regions R_{MC}. Between two memory cell regions R_{MC} mutually adjacent in the X direction, an insulating layer 102 of silicon nitride (Si₃N₄) or the like is disposed.

In the memory cell region R_{MC}, the memory layer ML includes two semiconductor layers 120 that are mutually spaced in the X direction. The memory layer ML includes an insulating layer 121 disposed on a side surface in the X direction of the semiconductor layer 120 and a semiconductor layer 122 disposed on a side surface in the X direction of the insulating layer 121. Between the two semiconductor layers 120, four electrodes 130, 140, 150, and 160 arranged in a Y direction are disposed. The electrode 140 is closer to the conductive layer 110 than the electrode 130. The electrode 150 is closer to the conductive layer 110 than the electrode 140. The electrode 160 is closer to the conductive layer 110 than the electrode 150. These four electrodes 130, 140, 150, and 160, for example, as illustrated in FIG. 1, penetrate the plurality of memory layers ML to extend in the Z direction. Insulating layers 141, 151, and 161 are disposed on outer peripheral surfaces of the three electrodes 140, 150, and 160, respectively. Between each of the four electrodes 130, 140, 150, and 160, an insulating layer 103 of silicon oxide (SiO₂) or the like is disposed.

Each configuration in the memory cell region R_{MC} constitutes the memory cell MC as illustrated in FIG. 3. The memory cell MC includes transistors Tr1 and Tr2 connected in series between a bit line BL and a source line SL. The transistors Tr1 and Tr2 are N-channel type field effect transistors. A gate electrode of the transistor Tr1 is connected to a select gate line SG. A gate electrode of the transistor Tr2 is connected to a control gate line CG via a node N1 and a capacitor Cap. The memory cell MC includes a transistor Tr3 connected between the node N1 and the bit line BL. The transistor Tr3 is an N-channel type field effect transistor. A gate electrode of the transistor Tr3 is connected to a transfer gate line TG.

The conductive layer 110 functions as the bit line BL. The conductive layer 110 may include, for example, a conductive layer of titanium nitride (TiN) or the like.

The semiconductor layer 120 functions as channel regions of the transistors Tr1 and Tr2. The semiconductor layer 120 includes, for example, a semiconductor layer of polycrystalline silicon (Si) or the like. The semiconductor layer 120 extends in the Y direction and is connected to the conductive layer 110 at its one end portion in the Y direction. A part of a side surface on one side in the X direction of the semiconductor layer 120 is connected to the electrode 130, and the other part is covered by the insulating layer 121.

At a connecting portion with the conductive layer 110 of the semiconductor layer 120, an impurity region 123 is disposed. At a connecting portion with the electrode 130 of the semiconductor layer 120, an impurity region 124 is disposed. The impurity regions 123 and 124 contain, for example, N-type impurities such as phosphorus (P).

The insulating layer 121 functions as gate insulating layers of the transistors Tr1 and Tr2. The insulating layer 121 includes, for example, an insulating layer of silicon oxide (SiO₂) or the like. A part of a side surface on one side in the X direction of the insulating layer 121 is connected to an insulating layer 141, and the other part is covered by the semiconductor layer 122.

The semiconductor layer 122 functions as the gate electrode of the transistor Tr2, the node N1, and one electrode of the capacitor Cap. The semiconductor layer 122 functions as an electric charge accumulating layer that can accumulate electric charge. The semiconductor layer 122 may include, for example, a semiconductor layer of polycrystalline silicon (Si) containing N-type impurities such as phosphorus (P) or P-type impurities such as boron (B), or the like, or may include a metal such as tungsten (W). The semiconductor layer 122 extends in the Y direction. One end portion in the Y direction of the semiconductor layer 122 is electrically connected to the conductive layer 110 via a semiconductor layer 125 and an impurity region 126. A part of a side surface on one side in the X direction of the semiconductor layer 122 is connected to an insulating layer 151 and the other part is covered by the insulating layer 103.

The semiconductor layer 125 functions as the channel region of the transistor Tr3. The semiconductor layer 125 is opposed to the electrode 160.

The semiconductor layer 125 may include, for example, metal oxide (oxide semiconductor) that functions as a semiconductor. The semiconductor layer 125 may include, for example, indium gallium zinc oxide (InGaZnO), indium oxide (InO), indium zinc oxide (InZnO), zinc oxide (ZnO), indium gallium silicon oxide (InGaSiO), indium aluminum zinc oxide (InAlZnO), indium tungsten oxide (InWO), indium tin oxide (InSnO), tin oxide (SnO), copper oxide (CuO), titanium oxide (TiO), or tungsten oxide (WO). Furthermore, the semiconductor layer 125 may include a stacked film made of them.

The impurity region 126 includes, for example, a semiconductor layer of polycrystalline silicon (Si) containing N-type impurities such as phosphorus (P), or the like.

The electrode 130 functions as the source line SL. The electrode 130 includes, for example, a conductive layer 131 of titanium nitride (TiN) or the like and a conductive layer 132 of tungsten (W) or the like.

The electrode 140 functions as the gate electrode of the transistor Tr1 and the select gate line SG. The electrode 140 includes, for example, a conductive layer of titanium nitride (TiN) or the like and a conductive layer of tungsten (W) or the like. The electrode 140 is opposed to the semiconductor layer 120 via the insulating layers 121 and 141.

The insulating layer 141, for example, functions as the gate insulating layer of the transistor Tr1. The insulating layer 141 includes, for example, an insulating layer of silicon oxide (SiO₂).

The electrode 150 functions as the other electrode of the capacitor Cap and the control gate line CG. The electrode 150 includes, for example, the conductive layer of titanium nitride (TiN) or the like and the conductive layer of tungsten (W) or the like. The electrode 150 is opposed to the semiconductor layer 122 via the insulating layer 151.

The insulating layer 151 functions, for example, as the insulating layer between the electrodes of the capacitor Cap. The insulating layer 151 includes, for example, the insulating layer of silicon oxide (SiO₂) or the like.

The electrode 160 functions as the gate electrode of the transistor Tr3 and the transfer gate line TG. The electrode 160 includes, for example, a conductive layer of titanium nitride (TiN) or the like and a conductive layer of tungsten (W) or the like. The electrode 160 is opposed to the semiconductor layer 125 via the insulating layer 161.

The insulating layer 161 functions, for example, as a gate insulating layer of the transistor Tr3. The insulating layer 161 includes, for example, an insulating layer of silicon oxide (SiO₂).

### [Manufacturing Method]

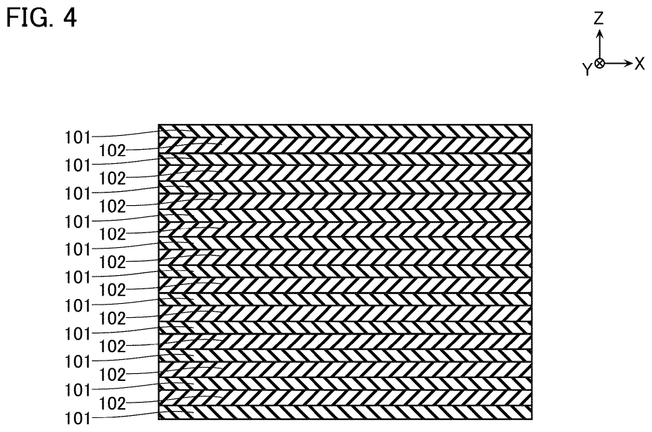

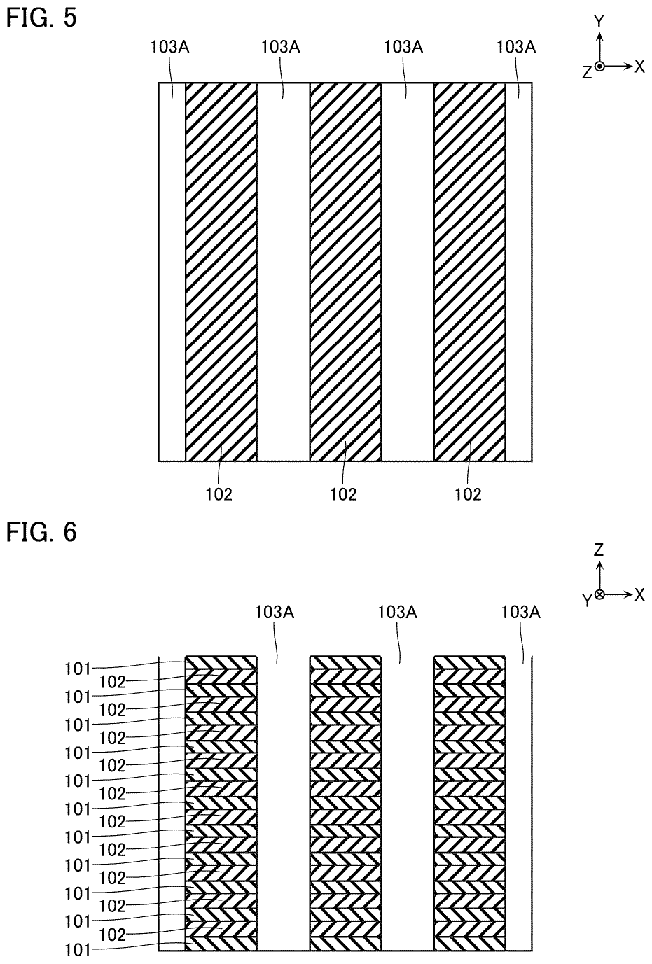

FIG. 4 to FIG. 40 are schematic cross-sectional views for describing a manufacturing method of the semiconductor memory device according to the first embodiment. FIGS. 5, 7, 9, 11, 13, 15, 17, 19, 21, 23, 25, 27, 29, 31, 33, 35, 37, and 39 illustrate XY cross-sectional surfaces corresponding to FIG. 2. FIGS. 4, 6, 8, 10, 12, 14, 16, 20, 22, and 24 illustrate XZ cross-sectional surfaces at a position corresponding to the electrode 130. FIG. 18 illustrates YZ cross-sectional surface at a position corresponding to the insulating layer 102. FIGS. 26, 28, and 30 illustrate XZ cross-sectional surfaces at a position corresponding to the electrode 140. FIGS. 32 and 34 illustrate XZ cross-sectional surfaces at a position corresponding to the electrode 150. FIGS. 36, 38, and 40 illustrate XZ cross-sectional surfaces at a position corresponding to the electrode 160.

In the manufacturing method, for example, as illustrated in FIG. 4, a plurality of the insulating layers 101 and a plurality of the insulating layers 102 are alternately formed. This process is performed, for example, by Chemical Vapor Deposition (CVD) or the like. Next, for example, as illustrated in FIGS. 5 and 6, openings 103A are formed. As illustrated in FIG. 5, the openings 103A extend in the Y direction and are arranged in the X direction. As illustrated in FIG. 6, the openings 103A extend in the Z direction and penetrate the plurality of insulating layers 101 and the plurality of insulating layers 102, which are arranged in the Z direction. This process is performed, for example, by Reactive Ion Etching (RIE) or the like.

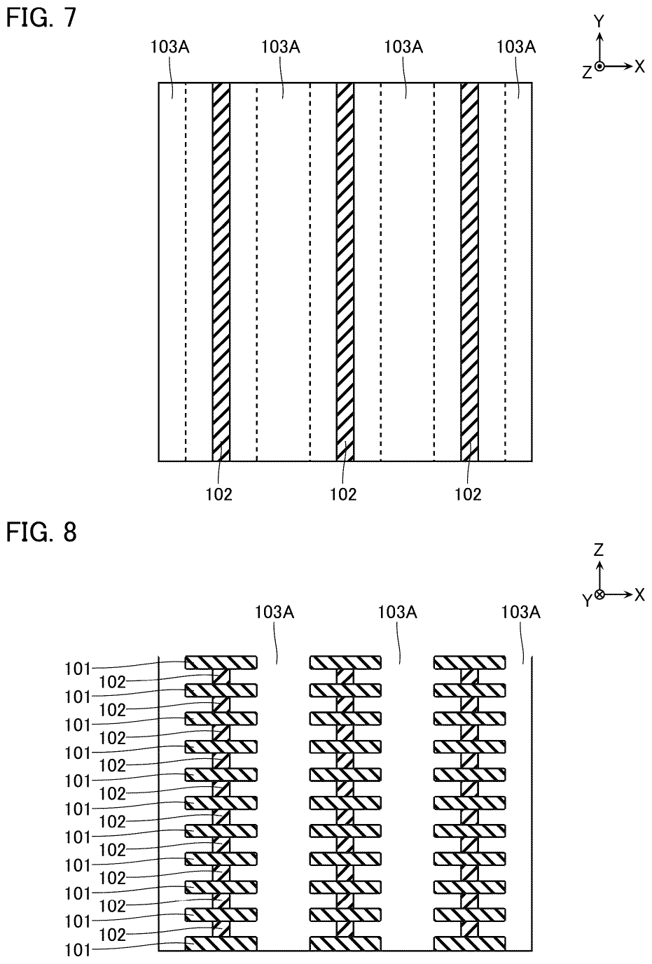

Next, for example, as illustrated in FIGS. 7 and 8, a part of the insulating layer 102 is removed, and parts of an upper surface and a lower surface of the insulating layer 101 are exposed. This process is performed, for example, by wet etching or the like.

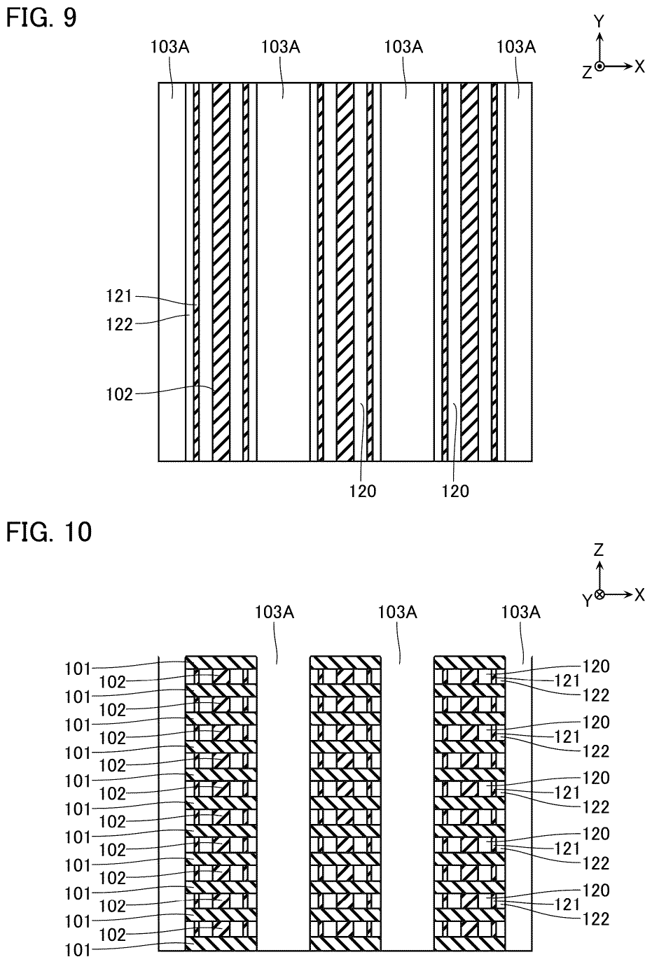

Next, for example, as illustrated in FIGS. 9 and 10, the semiconductor layer 120, the insulating layer 121, and the semiconductor layer 122 are formed. This process is performed, for example, by CVD, wet etching, oxidation treatment, or the like.

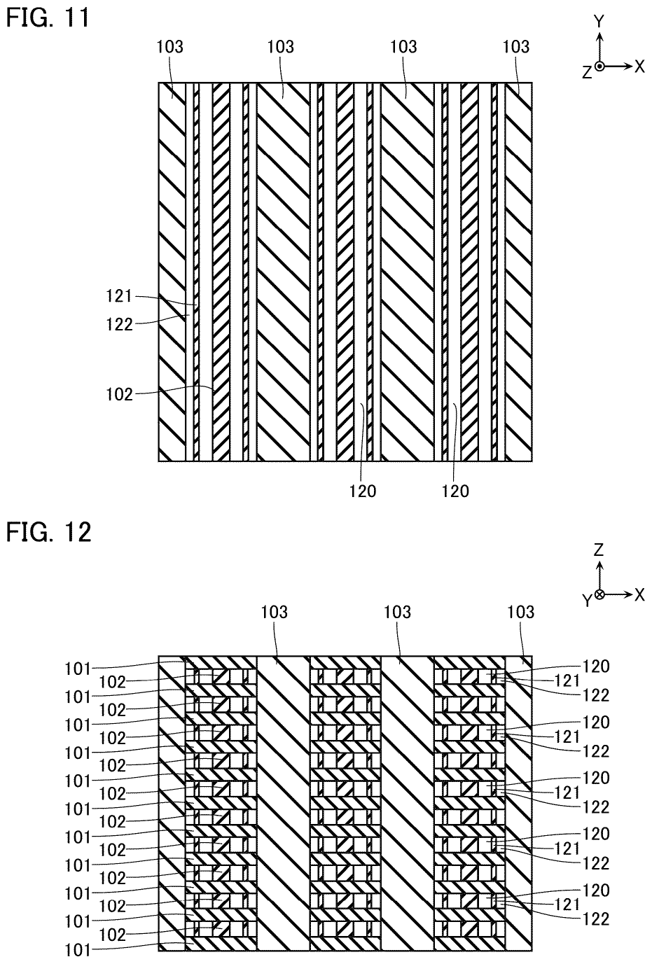

Next, for example, as illustrated in FIGS. 11 and 12, the insulating layer 103 is formed inside the opening 103A. This process is performed, for example, by CVD or the like.

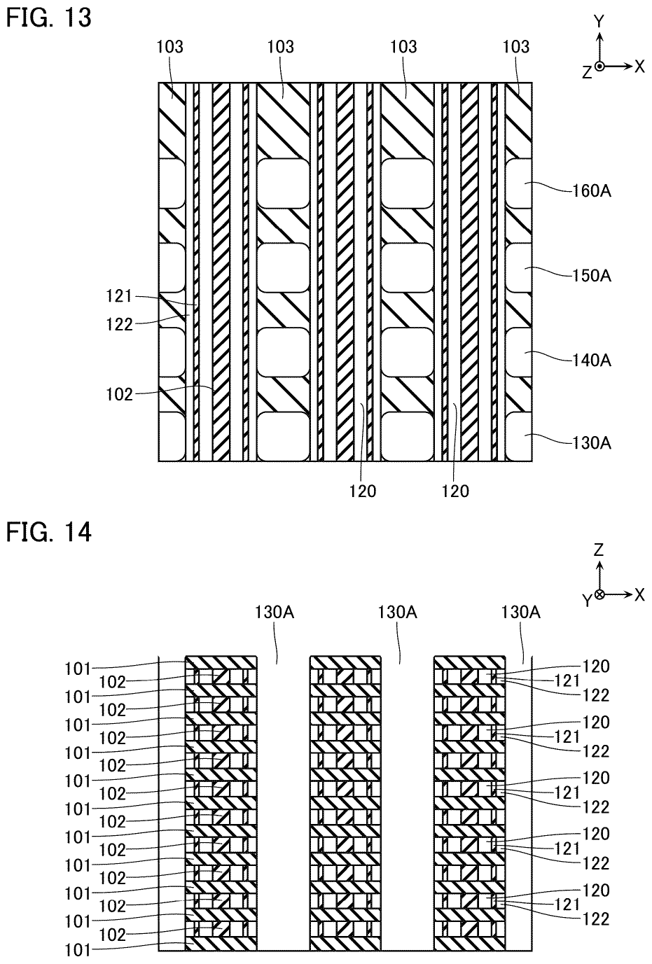

Next, for example, as illustrated in FIGS. 13 and 14, an opening 130A is formed at the position corresponding to the electrode 130. An opening 140A is formed at the position corresponding to the electrode 140. An opening 150A is formed at the position corresponding to the electrode 150. An opening 160A is formed at the position corresponding to the electrode 160. As illustrated in FIG. 14, these openings 130A, 140A, 150A, and 160A extend in the Z direction, and the side surfaces in the X direction of the plurality of insulating layers 101 and the plurality of semiconductor layers 122, which are arranged in the Z direction, are exposed. This process is performed, for example, by RIE or the like.

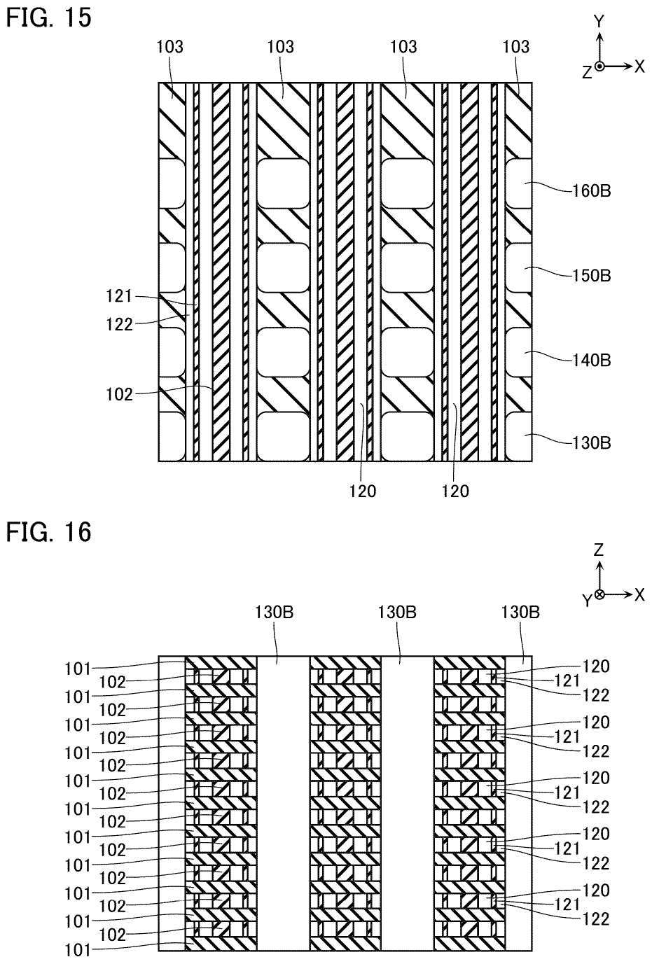

Next, for example, as illustrated in FIGS. 15 and 16, sacrifice layers 130B, 140B, 150B, and 160B each are formed inside the respective openings 130A, 140A, 150A, and 160A. This process is performed, for example, by CVD or the like.

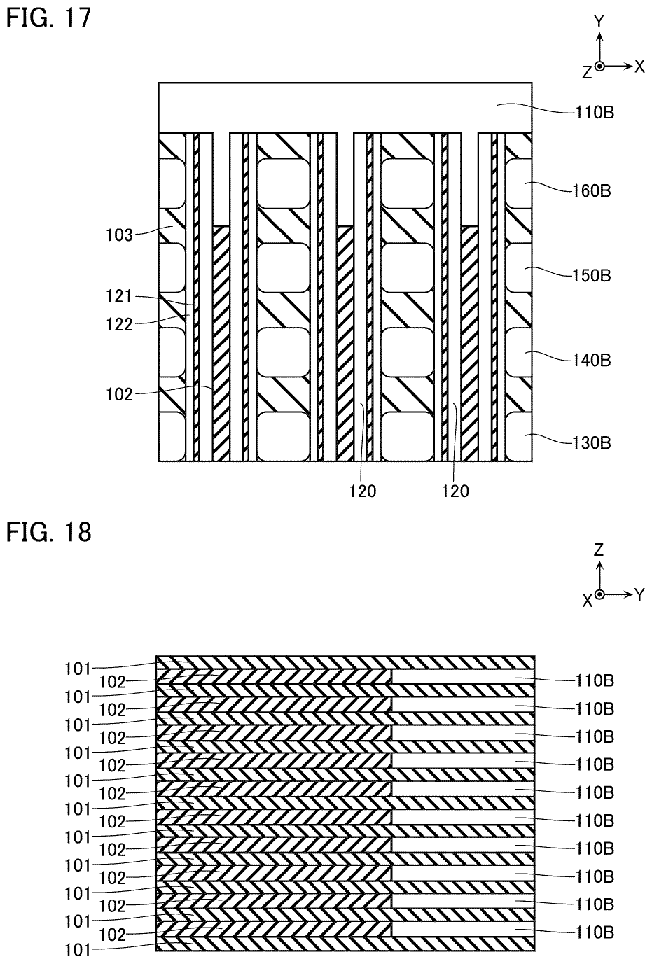

Next, for example, as illustrated in FIGS. 17 and 18, a sacrifice layer 110B is formed at the position corresponding to the conductive layer 110. In this process, for example, an opening extending in the X direction is formed. A part of the insulating layer 102 is removed by a method such as wet etching. The sacrifice layer 110B is formed by a method such as CVD.

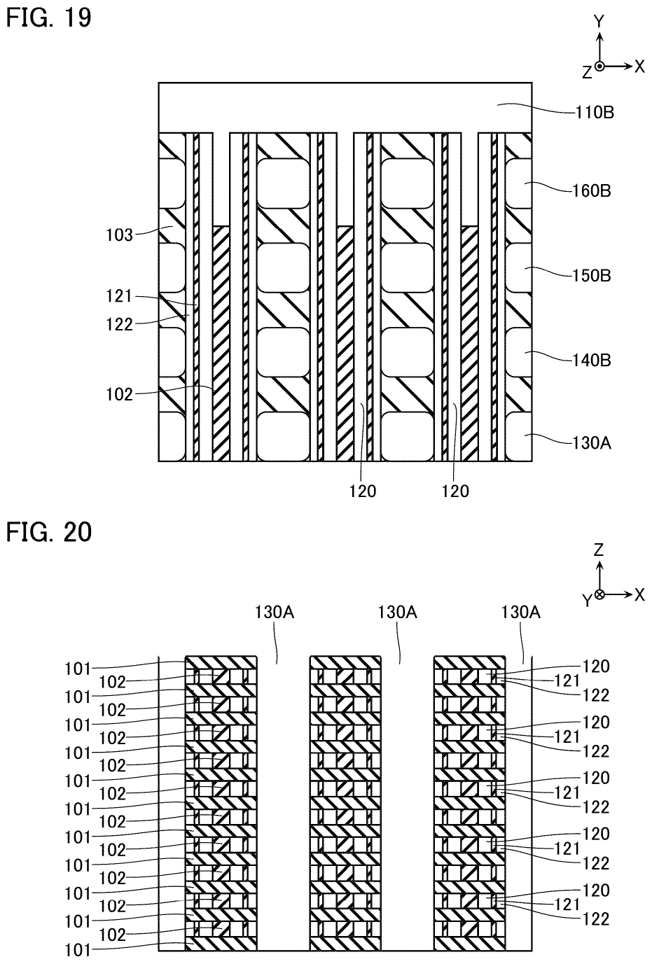

Next, for example, as illustrated in FIGS. 19 and 20, the sacrifice layer 130B is removed. This process is performed, for example, by wet etching or the like.

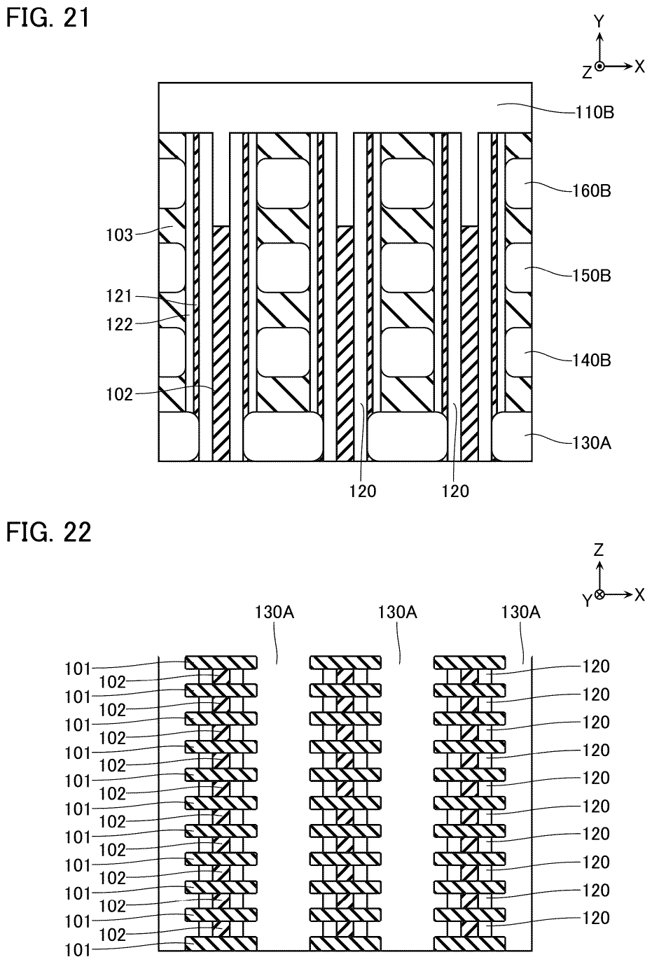

Next, for example, as illustrated in FIGS. 21 and 22, parts of the semiconductor layer 122 and the insulating layer 121 are removed, and parts of the upper surface and the lower surface of the insulating layer 101 and the side surface in the X direction of the semiconductor layer 120 are exposed. This process is performed, for example, by wet etching or the like.

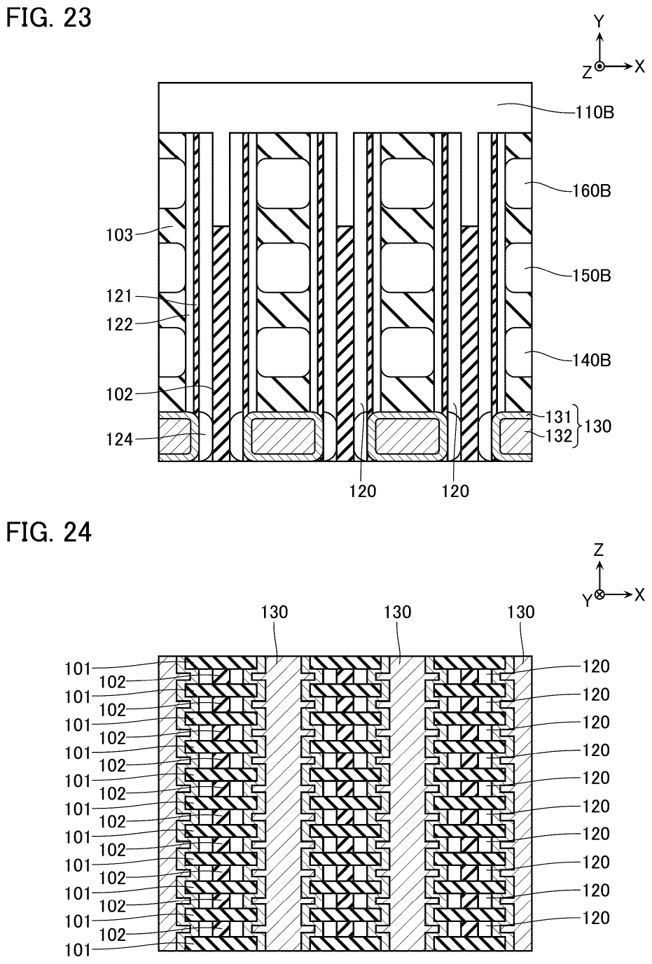

Next, for example, as illustrated in FIGS. 23 and 24, the impurity region 124 and the electrode 130 are formed. This process is performed, for example, by CVD or the like.

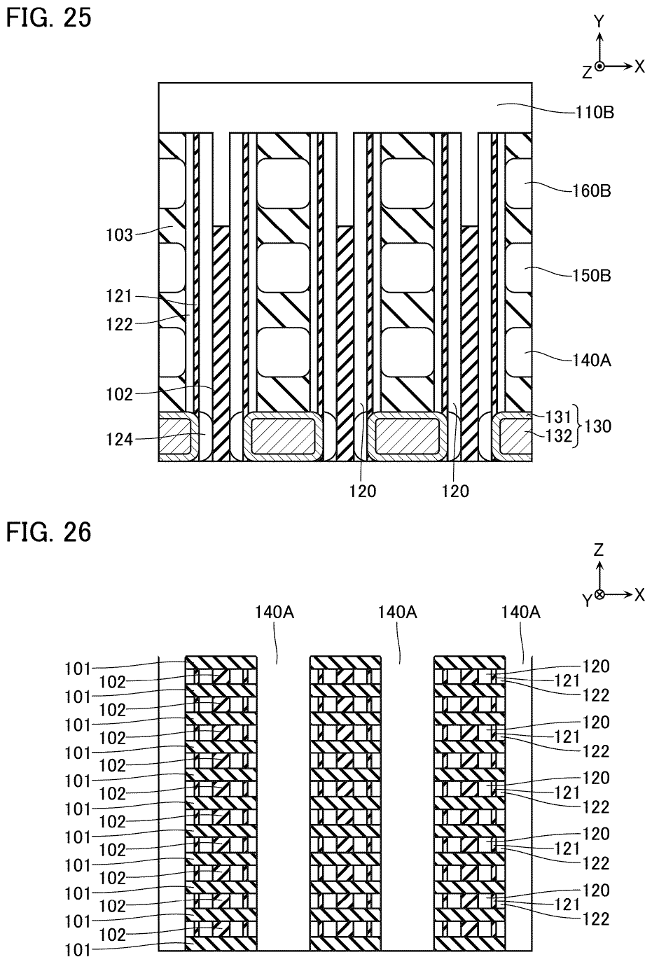

Next, for example, as illustrated in FIGS. 25 and 26, the sacrifice layer 140B is removed. This process is performed, for example, by wet etching or the like.

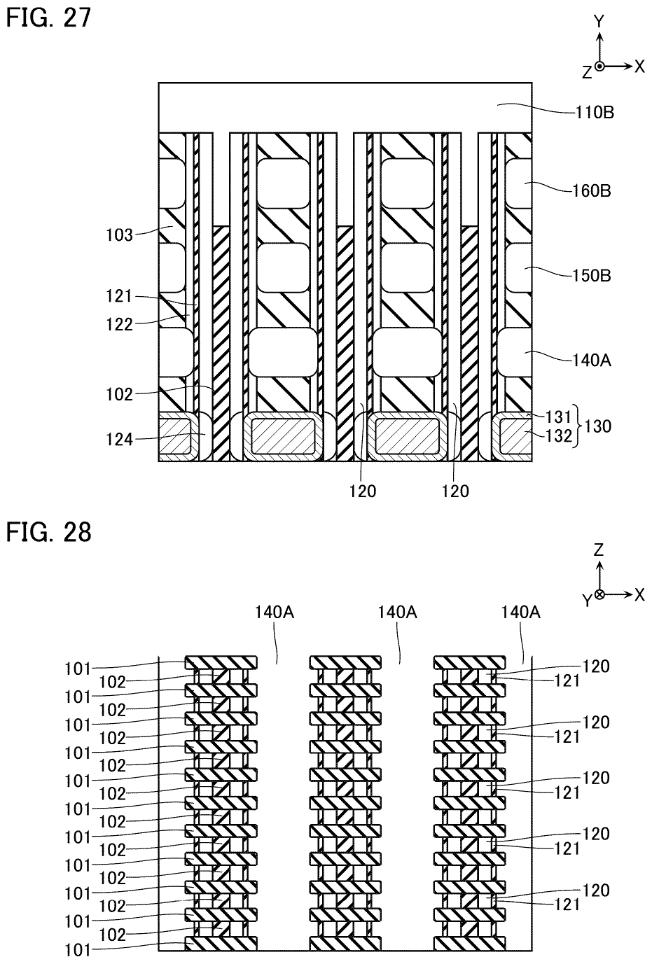

Next, for example, as illustrated in FIGS. 27 and 28, a part of the semiconductor layer 122 is removed, and parts of the upper surface and the lower surface of the insulating layer 101 and the side surface in the X direction of the insulating layer 121 are exposed. This process is performed, for example, by wet etching or the like.

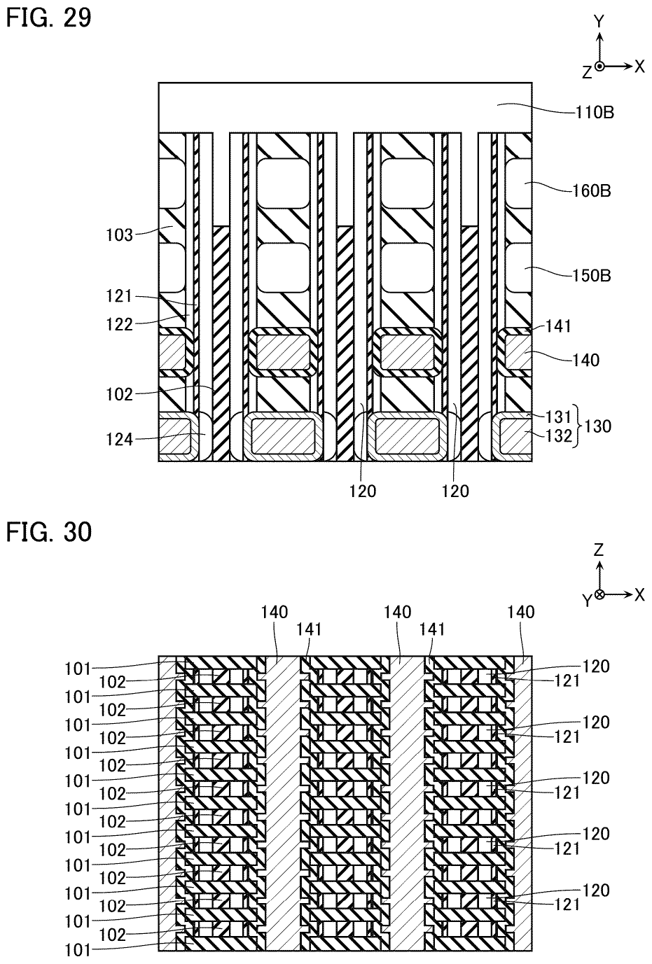

Next, for example, as illustrated in FIGS. 29 and 30, the insulating layer 141 and the electrode 140 are formed. This process is performed, for example, by CVD or the like.

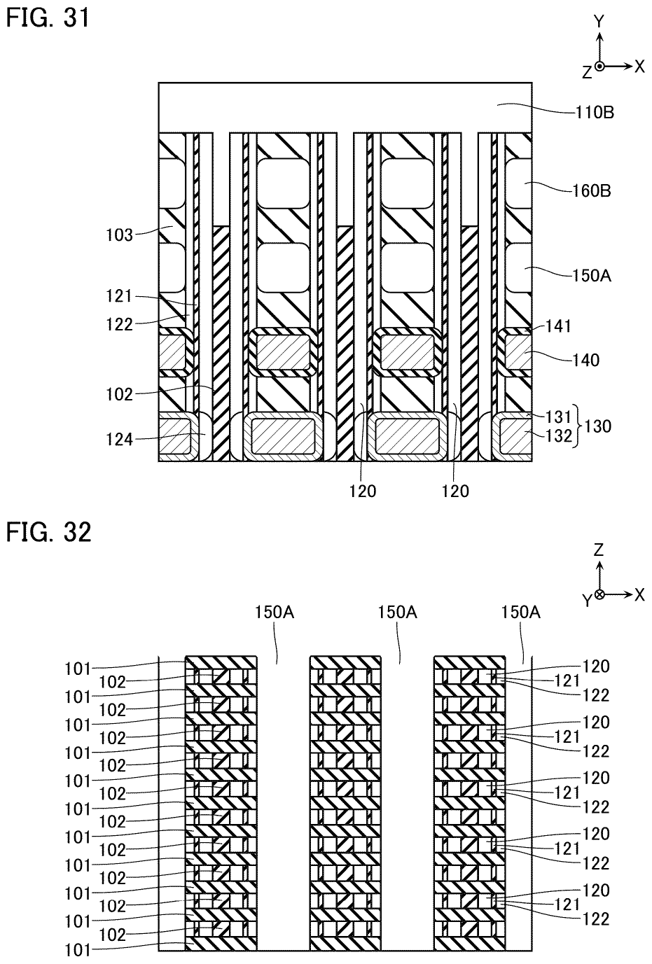

Next, for example, as illustrated in FIGS. 31 and 32, the sacrifice layer 150B is removed. This process is performed, for example, by wet etching or the like.

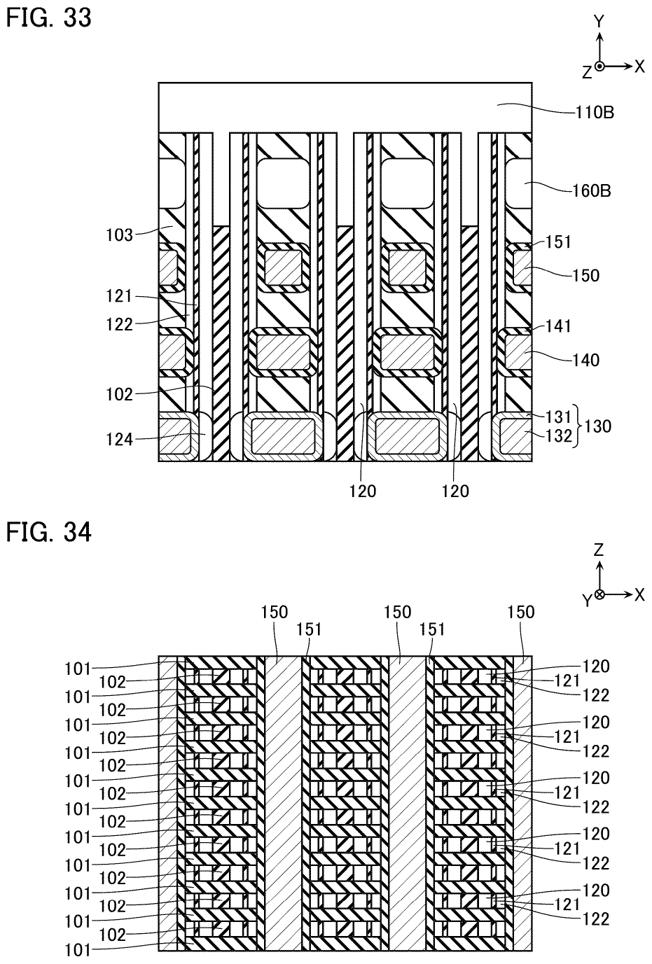

Next, for example, as illustrated in FIGS. 33 and 34, the insulating layer 151 and the electrode 150 are formed. This process is performed, for example, by CVD or the like.

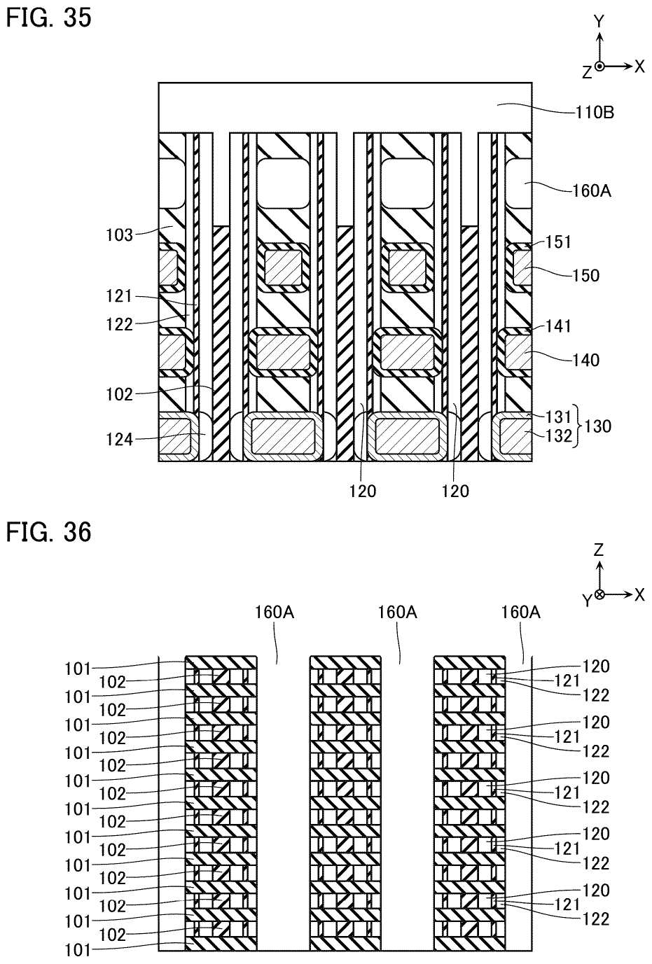

Next, for example, as illustrated in FIGS. 35 and 36, the sacrifice layer 160B is removed. This process is performed, for example, by wet etching or the like.

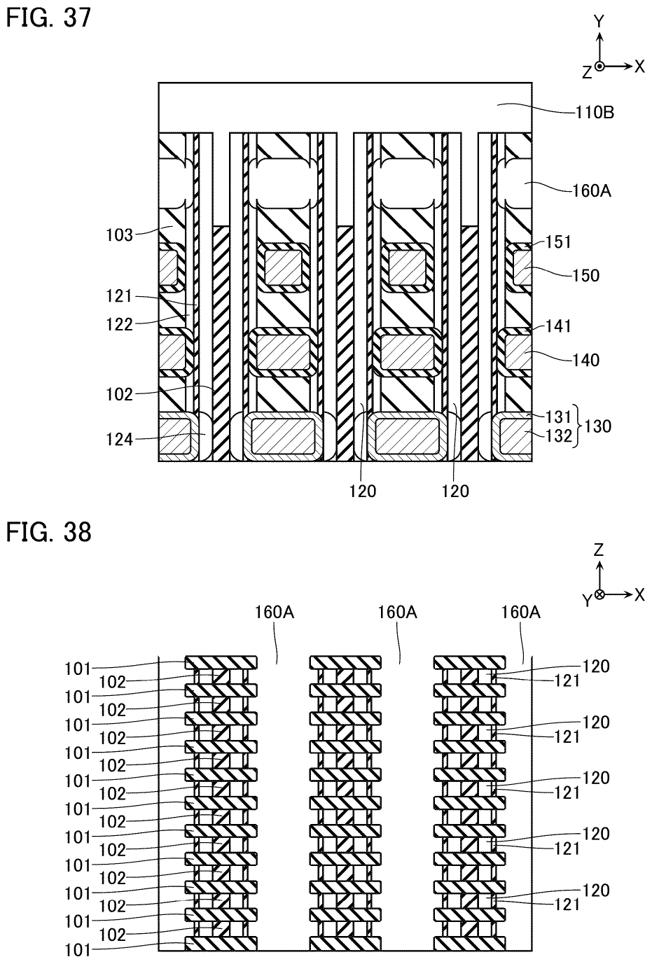

Next, for example, as illustrated in FIGS. 37 and 38, a part of the semiconductor layer 122 is removed, and parts of the upper surface and the lower surface of the insulating layer 101 and the side surface in the X direction of the insulating layer 121 are exposed. This process is performed, for example, by wet etching or the like.

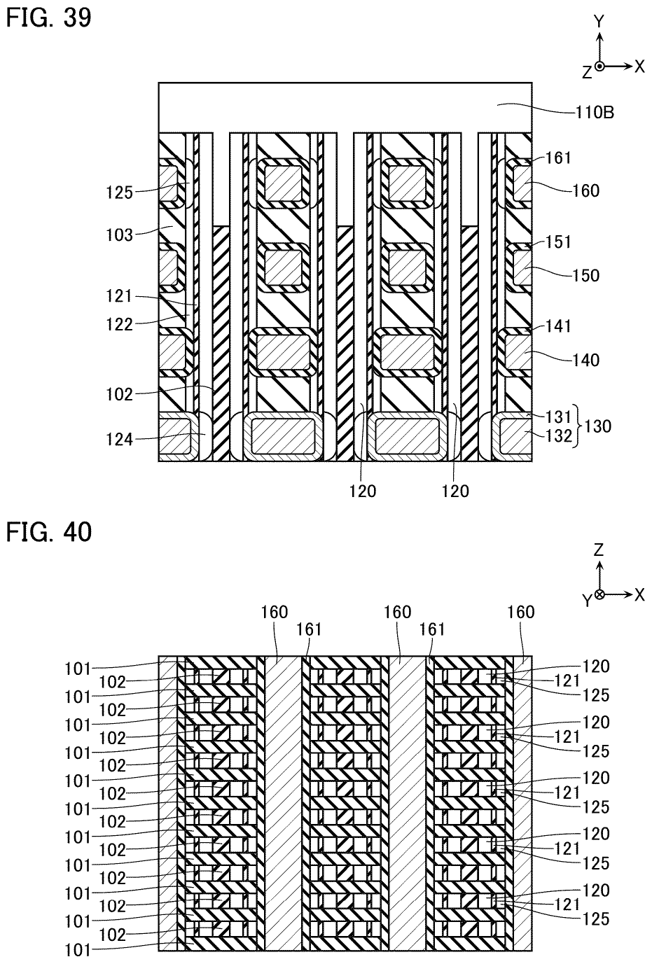

Next, for example, as illustrated in FIGS. 39 and 40, the semiconductor layer 125, the insulating layer 161, and the electrode 160 are formed. This process is performed, for example, by a method such as Atomic Layer Deposition (ALD), CVD, or wet etching.

Next, for example, as illustrated in FIGS. 1 and 2, the conductive layer 110 is formed. In this process, the sacrifice layer 110B is removed, for example, by a method such as wet etching. The conductive layer 110 is formed by a method such as CVD.

### [Read Operation]

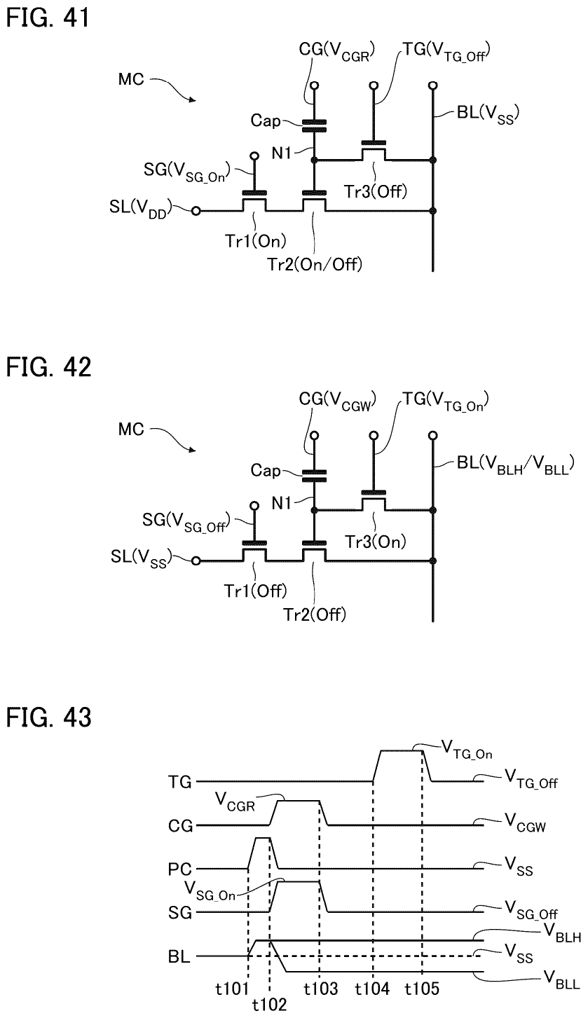

Next, with reference to FIG. 41, the read operation of the semiconductor memory device according to the embodiment is described. FIG. 41 is a schematic circuit diagram for describing the read operation.

In the semiconductor memory device according to the embodiment, electric charge is accumulated in the node N1 corresponding to data stored in the memory cell MC. For example, when data “1” is stored in the memory cell MC, positive electric charge may be accumulated in the node N1. On the other hand, when data “0” is stored in the memory cell MC, electric charge needs not be accumulated, or negative electric charge may be accumulated in the node N1.

In the read operation of the semiconductor memory device according to the embodiment, a ground voltage V_{SS} is applied to the bit line BL.

A voltage V_{TG_Off} is applied to the transfer gate line TG. A difference between the voltage V_{TG_Off} and the ground voltage V_{SS} is smaller than a threshold voltage of the transistor Tr3. The voltage V_{TG_Off} may be, for example, a voltage having a magnitude approximately the same as the ground voltage V_{SS} or may be a voltage having a negative polarity. Thus, the transistor Tr3 turns OFF.

A voltage V_{CGR} is applied to the control gate line CG. Thus, when positive electric charge has been accumulated in the node N1, the transistor Tr2 turns ON. On the other hand, when no electric charge has been accumulated in the node N1, the transistor Tr2 turns OFF.

A voltage V_{SG_On} is applied to the select gate line SG connected to a selected memory cell MC. A difference between the voltage V_{SG_On} and the ground voltage V_{SS} is larger than a threshold voltage of the transistor Tr1. Thus, the transistor Tr1 in the selected memory cell MC turns ON.

Voltages V_{SG_Off} are applied to the other select gate lines SG. A difference between the voltage V_{SG_Off} and the ground voltage V_{SS} is smaller than the threshold voltage of the transistor Tr1. The voltage V_{SG_Off} may be, for example, a voltage having a magnitude approximately the same as the ground voltage V_{SS} or may be a voltage having a negative polarity. Thus, the transistor Tr1 in an unselected memory cell MC turns OFF.

A voltage V_{DD} is applied to the source line SL.

Here, when positive electric charge has been accumulated in the node N1, the transistor Tr2 turns ON, and thus, a current flow through the bit line BL. On the other hand, when no electric charge has been accumulated in the node N1, the transistor Tr2 turns OFF, and thus, the current does not flow in the bit line BL. Therefore, by detecting the current or the voltage of the bit line BL, the data stored in the selected memory cell MC is detectable.

### [Write Operation]

Next, with reference to FIG. 42, the write operation of the semiconductor memory device according to the embodiment is described. FIG. 42 is a schematic circuit diagram for describing the write operation.

In the write operation of the semiconductor memory device according to the embodiment, in storing the data “1” in the memory cell MC, a voltage V_{BLH} is applied to the bit line BL. On the other hand, in storing the data “0” in the memory cell MC, a voltage V_{BLL} is applied to the bit line BL. The voltage V_{BLL} is, for example, smaller than the voltage V_{BLH}.

In addition, a voltage V_{TG_On} is applied to the transfer gate line TG connected to the selected memory cell MC. Differences between the voltage V_{TG_On} and the voltages V_{BLH} and V_{BLL} are larger than the threshold voltage of the transistor Tr3. Thus, the transistor Tr3 in the selected memory cell MC turns ON.

The voltages V_{TG_Off} are applied to the other transfer gate lines TG.

A voltage V_{CWG} is applied to the control gate line CG. The voltage V_{CGW} may be, for example, a voltage smaller than the voltage V_{CGR}. The voltage V_{CGW} may be, for example, a voltage having a magnitude approximately the same as the voltage V_{BLL} or may be a voltage larger than the voltage V_{BLL} and smaller than the voltage V_{BLH}.

Here, when the voltage V_{BLH} has been applied to the bit line BL, electric charge is accumulated in the capacitor Cap. On the other hand, when the voltage V_{BLL} has been applied to the bit line BL, electric charge is not accumulated in the capacitor Cap, or electric charge with a reversed polarity is accumulated in the capacitor Cap.

In addition, the voltage V_{SG_Off} is applied to the select gate line SG to cause the transistor Tr1 to turn OFF.

### [Data Inversion Operation]

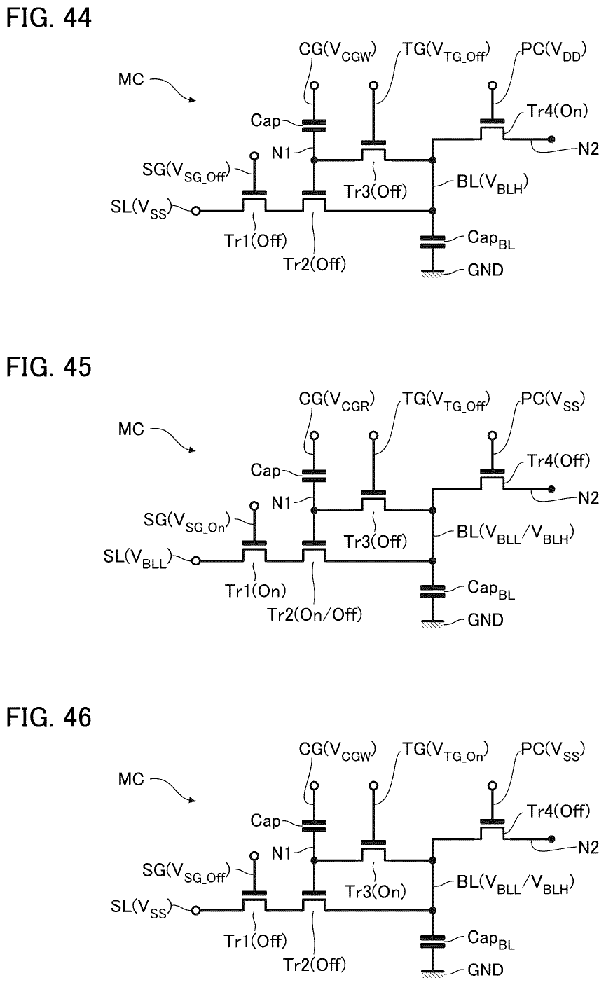

Next, with reference to FIG. 43 to FIG. 46, the data inversion operation of the semiconductor memory device according to the embodiment is described. FIG. 43 is a schematic waveform diagram for describing the data inversion operation. FIG. 44 to FIG. 46 are schematic circuit diagrams for describing the data inversion operation.

In FIG. 44 to FIG. 46, in addition to the configuration in the memory cell MC, a node N2 and a transistor Tr4 are indicated. The node N2 is electrically connected to the bit line BL and a capacitor Cap_{BL} associated with the bit line BL via the transistor Tr4. A signal line PC is connected to a gate electrode of the transistor Tr4.

In the semiconductor memory device according to the embodiment, it is possible to invert the data stored in the memory cell MC without using a sense amplifier circuit, a latch circuit, and the like. That is, it is possible to store the data “0” to the memory cell MC where the data “1” has been stored, and to store the data “1” to the memory cell MC where the data “0” has been stored.

At timing t101 (FIG. 43) of the data inversion operation, as illustrated in in FIG. 44, the voltage V_{BLH} is applied to the node N2. The voltage V_{DD} is applied to the signal line PC. A difference between the voltage V_{DD} and the voltage V_{BLH} is larger than the threshold voltage of the transistor Tr4. Consequently, the transistor Tr4 turns ON, and the voltage of the bit line BL is charged up to the voltage V_{BLH}. In addition, the voltage V_{TG_Off} is applied to the transfer gate line TG to cause the transistor Tr3 to turn OFF. Furthermore, the voltage V_{CGW} is applied to the control gate line CG to cause the transistor Tr2 to turn OFF. In addition, the voltage V_{SG_Off} is applied to the select gate line SG to cause the transistor Tr1 to turn OFF.

At timing t102 (FIG. 43) of the data inversion operation, as illustrated in in FIG. 45, the voltage V_{BLL} is applied to the source line SL. The voltage V_{SG_On} is applied to the select gate line SG. A difference between the voltage V_{SG_On} and the voltage V_{BLL} is larger than the threshold voltage of the transistor Tr1. Consequently, the transistor Tr1 turns ON. In addition, the voltage V_{CGR} is applied to the control gate line CG. Here, when positive electric charge has been accumulated in the node N1, the transistor Tr2 turns ON. On the other hand, when no electric charge has been accumulated in the node N1, the transistor Tr2 turns OFF. Furthermore, the voltage V_{TG_Off} is applied to the transfer gate line TG to cause the transistor Tr3 to turn OFF. In addition, the ground voltage V_{SS} is applied to the signal line PC to cause the transistor Tr4 to turn OFF.

In such state, when positive electric charge has been accumulated in the node N1, the transistor Tr2 turns ON, and thus, the voltage V_{BLL} is transferred to the bit line BL. On the other hand, when no electric charge has been accumulated in the node N1, the transistor Tr2 turns OFF, and thus, the voltage of the bit line BL is maintained at the voltage V_{BLH}.

At timing t103 (FIG. 43) of the data inversion operation, the voltage V_{SG_Off} is applied to the select gate line SG to cause the transistor Tr1 to turn OFF. Furthermore, the voltage V_{CGW} is applied to the control gate line CG to cause the transistor Tr2 to turn OFF. In addition, the voltage V_{TG_Off} is applied to the transfer gate line TG to cause the transistor Tr3 to turn OFF. Furthermore, the ground voltage V_{SS} is applied to the signal line PC to cause the transistor Tr4 to turn OFF.

At timing t104 (FIG. 43) of the data inversion operation, as illustrated in FIG. 46, the voltage V_{SG_Off} is applied to the select gate line SG to cause the transistor Tr1 to turn OFF. Furthermore, the voltage V_{CGW} is applied to the control gate line CG to cause the transistor Tr2 to turn OFF. In addition, the voltage V_{TG_On} is applied to the transfer gate line TG to cause the transistor Tr3 to turn ON. Furthermore, the ground voltage V_{SS} is applied to the signal line PC to cause the transistor Tr4 to turn OFF.

Here, when positive electric charge has been accumulated in the node N1 at a time point of starting the data inversion operation, the voltage of the bit line BL is the voltage V_{BLL}. Consequently, positive electric charge in the node N1 is discharged to the bit line BL. On the other hand, when no electric charge has been accumulated in the node N1 at a time point of starting the data inversion operation, the voltage of the bit line BL is the voltage V_{BLH}. Consequently, positive electric charge is accumulated in the node N1.

### [Self-Refresh Operation]

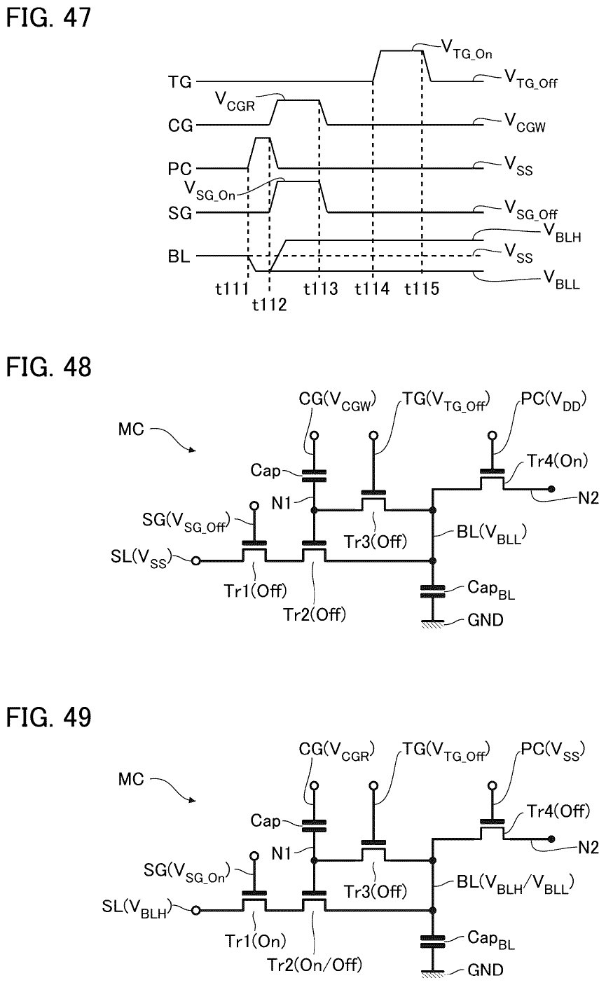

Next, with reference to FIG. 47 to FIG. 50, the self-refresh operation of the semiconductor memory device according to the embodiment is described. FIG. 47 is a schematic waveform diagram for describing the self-refresh operation. FIG. 48 to FIG. 50 are schematic circuit diagrams for describing the self-refresh operation. In FIG. 48 to FIG. 50, in addition to the configuration of the memory cell MC, the node N2 and the transistor Tr4 are indicated.

The operation at timing t111 (FIG. 47) of the self-refresh operation is basically the same as the operation at timing t101 of the data inversion operation. However, at timing t111, as illustrated in FIG. 48, the voltage V_{BLL} is applied to the node N2 instead of the voltage V_{BLH}.

The operation at timing t112 (FIG. 47) of the self-refresh operation is basically the same as the operation at timing t102 of the data inversion operation. However, at timing t112, as illustrated in FIG. 49, the voltage V_{BLH} is applied to the source line SL instead of the voltage V_{BLL}.

In such state, when positive electric charge has been accumulated in the node N1, the transistor Tr2 turns ON, and thus, the voltage V_{BLH} is transferred to the bit line BL. On the other hand, when no electric charge has been accumulated in the node N1, the transistor Tr2 turns OFF, and thus, the voltage of the bit line BL is maintained at the voltage V_{BLL}.

The operation at timing t113 (FIG. 47) of the self-refresh operation is the same as the operation at timing t103 of the data inversion operation.

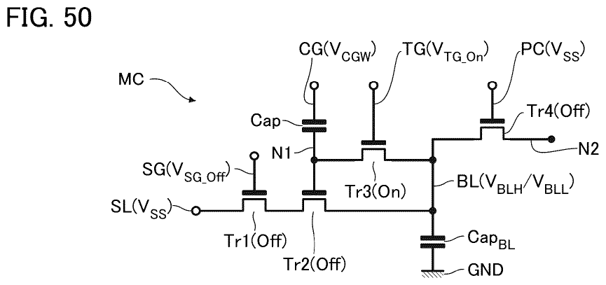

The operation at timing t114 (FIG. 47) of the self-refresh operation is, as illustrated in FIG. 50, the same as the operation at timing t104 of the data inversion operation.

Here, when positive electric charge has been accumulated in the node N1 at a time point of starting the self-refresh operation, the voltage of the bit line BL is the voltage V_{BLH}. Consequently, positive electric charge is accumulated to the node N1. On the other hand, when no electric charge has been accumulated in the node N1 at a time point of starting the self-refresh operation, the voltage of the bit line BL is the voltage V_{BLL}. Consequently, positive electric charge in the node N1 is discharged to the bit line BL, and the node N1 is maintained at a state of no accumulated electric charge.

### Second Embodiment

### [Configuration]

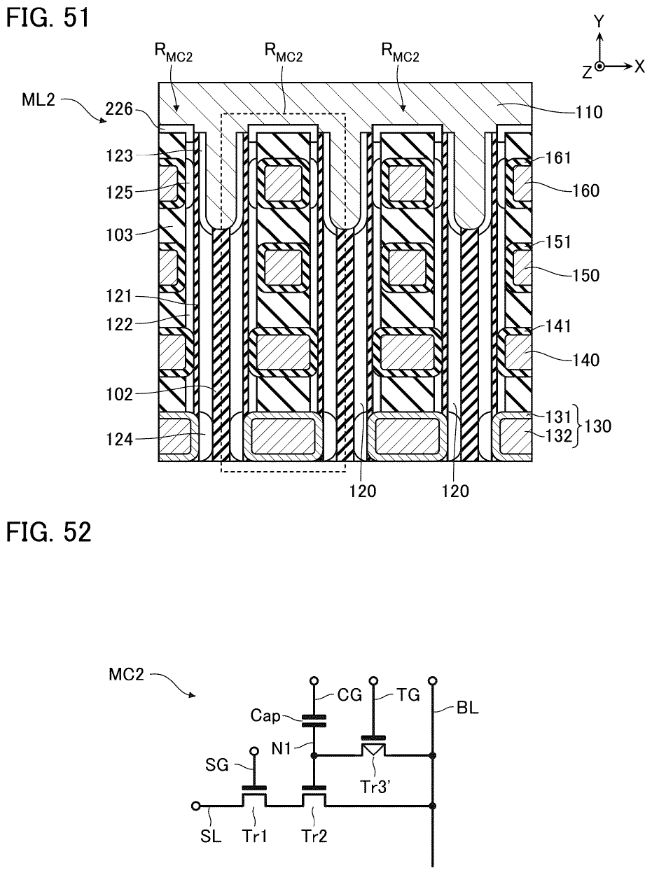

FIG. 51 is a schematic plan view illustrating a part of a configuration of a semiconductor memory device according to the second embodiment. FIG. 52 is a schematic circuit diagram illustrating a part of the configuration of the semiconductor memory device according to the embodiment.

The semiconductor memory device according to the second embodiment is basically configured similarly to the semiconductor memory device according to the first embodiment. However, the semiconductor memory device according to the second embodiment includes a memory layer ML2, instead of the memory layer ML.

As illustrated in FIG. 51, the memory layer ML2 is basically configured similarly to the memory layer ML. However, the memory layer ML2 includes a memory cell region R_{MC2}, instead of the memory cell region R_{MC}. The memory cell region R_{MC2} is basically configured similarly to the memory cell region R_{MC}. However, memory cell region R_{MC2} includes an impurity region 226, instead of the impurity region 126. The impurity region 226 is basically configured similarly to the impurity region 126. However, the impurity region 126 contains the N-type impurities such as phosphorus (P). On the other hand, the impurity region 226 contains P-type impurities such as boron (B).

Each configuration in the memory cell region R_{MC2} constitutes a memory cell MC2 as illustrated in FIG. 52. The memory cell MC2 is basically configured similarly to the memory cell MC. However, the memory cell MC2 includes a transistor Tr3′, instead of the transistor Tr3. The transistor Tr3′ is basically configured similarly to the transistor Tr3. However, While the transistor Tr3 is the N-channel type field effect transistor, the transistor Tr3′ is a P-channel type field effect transistor.

### [Read Operation]

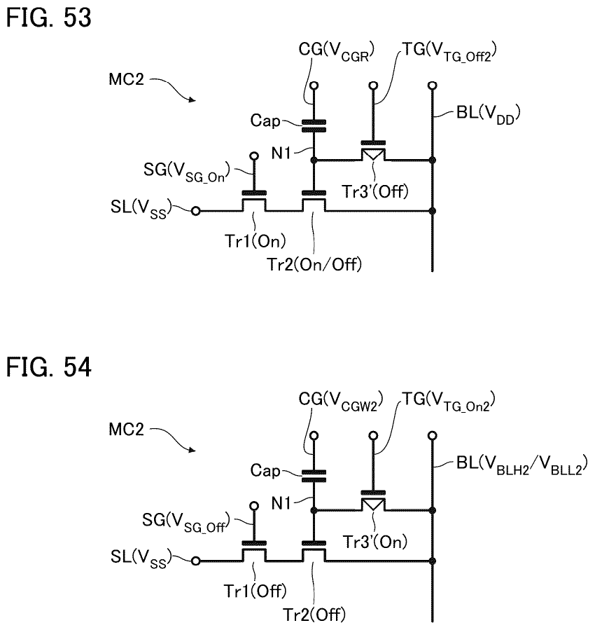

Next, with reference to FIG. 53, the read operation of the semiconductor memory device according to the embodiment is described. FIG. 53 is a schematic circuit diagram for describing the read operation.

The read operation of the semiconductor memory device according to the embodiment is basically executed similarly to the read operation of the semiconductor memory device according to the first embodiment.

However, in the read operation of the semiconductor memory device according to the embodiment, the voltage V_{DD} is applied to the bit line BL, and the ground voltage V_{SS} is applied to the source line SL.

Furthermore, in the read operation of the semiconductor memory device according to the embodiment, a voltage V_{TG_Off2} is applied to the transfer gate line TG. A difference between the voltage V_{TG_Off2} and the voltage V_{DD} is larger than the threshold voltage of the transistor Tr3′. Thus, the transistor Tr3′ turns OFF.

### [Write Operation]

Next, with reference to FIG. 54, the write operation of the semiconductor memory device according to the embodiment is described. FIG. 54 is a schematic circuit diagram for describing the write operation.

The write operation of the semiconductor memory device according to the embodiment is basically executed similarly to the write operation of the semiconductor memory device according to the first embodiment.

However, in the write operation of the semiconductor memory device according to the embodiment, in storing the data “1” in the memory cell MC2, a voltage V_{BLH2} is applied to the bit line BL. On the other hand, in storing the data “0” in the memory cell MC2, a voltage V_{BLL2} is applied to the bit line BL. The voltage V_{BLL2} is, for example, smaller than the voltage V_{BLH2}.

A voltage V_{TG_On2} is applied to the transfer gate line TG connected to a selected memory cell MC2. A difference between the voltage V_{TG_On2} and the voltages V_{BLH2} and a difference between the voltage V_{TG_On2} and the voltage V_{BLL2} are equal to or less than a threshold voltage of the transistor Tr3′. Thus, the transistor Tr3′ turns ON. Furthermore, a voltage V_{CGW2} is applied to the control gate line CG. The voltage V_{CGW2} may be, for example, a voltage larger than the voltage V_{CGR} and smaller than the voltage V_{DD}. The voltage V_{CGW2} may be, for example, a voltage having a magnitude approximately the same as the voltage V_{BLL2} and may be a voltage larger than the voltage V_{BLL2} and smaller than the voltage V_{BLH2}.

### Third Embodiment

### [Configuration]

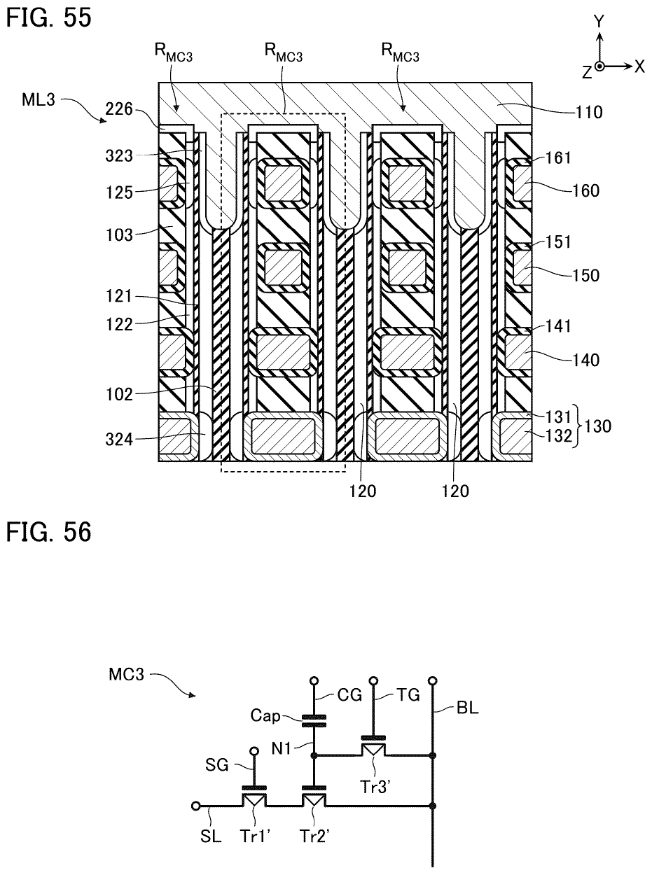

FIG. 55 is a schematic plan view illustrating a part of a configuration of a semiconductor memory device according to the third embodiment. FIG. 56 is a schematic circuit diagram illustrating a part of the configuration of the semiconductor memory device according to the embodiment.

The semiconductor memory device according to the third embodiment is basically configured similarly to the semiconductor memory device according to the second embodiment. However, the semiconductor memory device according to the third embodiment includes a memory layer ML3, instead of the memory layer ML2.

As illustrated in FIG. 55, the memory layer ML3 is basically configured similarly to the memory layer ML2. However, the memory layer ML3 includes a memory cell region R_{MC3}, instead of the memory cell region R_{MC2}. The memory cell region R_{MC3} is basically configured similarly to the memory cell region R_{MC2}. However, the memory cell region R_{MC3} includes impurity regions 323 and 324, instead of the impurity regions 123 and 124. The impurity regions 323 and 324 are basically configured similarly to the impurity regions 123 and 124. However, the impurity regions 123 and 124 contain the N-type impurities such as phosphorus (P). On the other hand, the impurity regions 323 and 324 contain P-type impurities such as boron (B).

Each configuration in the memory cell region R_{MC3} constitutes a memory cell MC3 as illustrated in FIG. 56. The memory cell MC3 is basically configured similarly to the memory cell MC2. However, the memory cell MC3 includes transistors Tr1′ and Tr2′, instead of the transistors Tr1 and Tr2. The transistors Tr1′ and Tr2′ are basically configured similarly to the transistors Tr1 and Tr2. However, While the transistors Tr1 and Tr2 are the N-channel type field effect transistors, the transistors Tr1′ and Tr2′ are a P-channel type field effect transistors.

### [Read Operation]

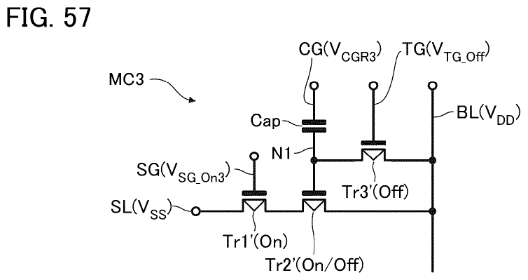

Next, with reference to FIG. 57, the read operation of the semiconductor memory device according to the embodiment is described. FIG. 57 is a schematic circuit diagram for describing the read operation.

The read operation of the semiconductor memory device according to the embodiment is basically executed similarly to the read operation of the semiconductor memory device according to the second embodiment.

However, in the read operation of the semiconductor memory device according to the embodiment, a voltage V_{CGR3} is applied to the control gate line CG. Thus, when positive electric charge has been accumulated in the node N1, the transistor Tr2′ turns OFF. On the other hand, when no electric charge has been accumulated in the node N1, the transistor Tr2′ turns ON.

In the read operation of the semiconductor memory device according to the embodiment, a voltage V_{SG_On3} is applied to the select gate line SG connected to a selected memory cell MC3. A difference between the voltage V_{SG_On3} and the voltage V_{DD} is equal to or less than a threshold voltage of the transistor Tr1′. The voltage V_{SG_On3} may be, for example, a voltage of a negative polarity. Thus, the transistor Tr1′ in the selected memory cell MC3 turns ON.

Furthermore, in the read operation of the semiconductor memory device according to the embodiment, voltages V_{SG_Off3} are applied to the other select gate lines SG. A difference between the voltage V_{SG_Off3} and the voltage V_{DD} is larger than the threshold voltage of the transistor Tr1′. The voltage V_{SG_Off3} may be, for example, a voltage having a magnitude approximately the same as the ground voltage V_{SS}. Thus, the transistor Tr1′ in the selected memory cell MC3 turns OFF.

### [Write Operation]

The write operation of the semiconductor memory device according to the embodiment is executed similarly to the write operation of the semiconductor memory device according to the second embodiment.

### Fourth Embodiment

### [Configuration]

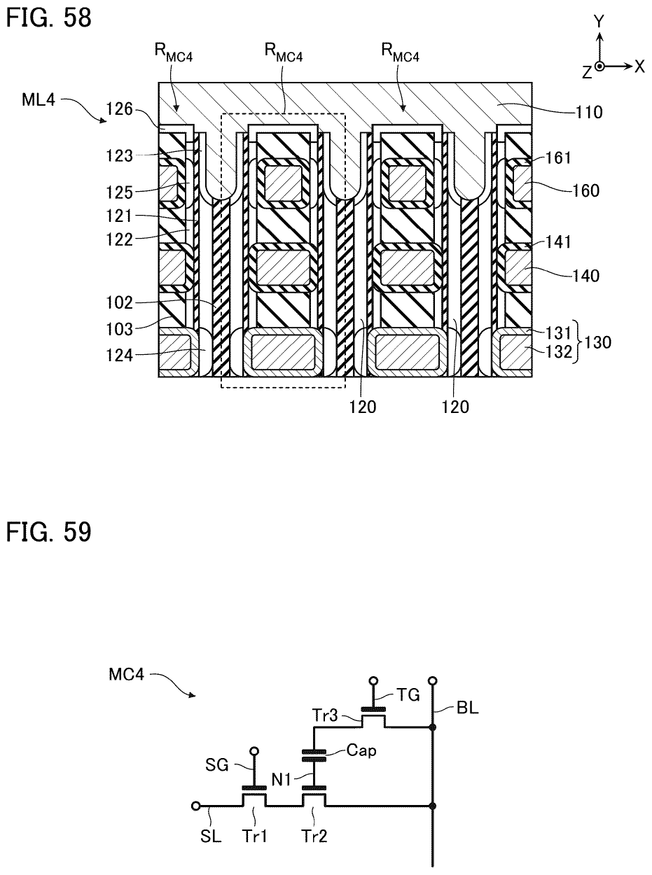

FIG. 58 is a schematic plan view illustrating a part of a configuration of a semiconductor memory device according to the fourth embodiment. FIG. 59 is a schematic circuit diagram illustrating a part of the configuration of the semiconductor memory device according to the embodiment.

The semiconductor memory device according to the fourth embodiment is basically configured similarly to the semiconductor memory device according to the first embodiment. However, the semiconductor memory device according to the fourth embodiment includes a memory layer ML4, instead of the memory layer ML.

As illustrated in FIG. 58, the memory layer ML4 includes a plurality of memory cell regions R_{MC4} arranged in the X direction and the conductive layer 110 extending in the X direction along the plurality of memory cell regions R_{MC4}. Between two memory cell regions R_{MC4} mutually adjacent in the X direction, the insulating layer 102 of silicon nitride (Si₃N₄) or the like is disposed.

The structure in the memory cell region R_{MC4} is basically similar to the structure in the memory cell region R_{MC}. However, the electrode 150 and the insulating layer 151 are not disposed in the memory cell region R_{MC4}.

Each configuration in the memory cell region R_{MC4} configures a memory cell MC4 as illustrated in FIG. 59. The memory cell MC4 is basically configured similarly to the memory cell MC. However, the memory cell MC4 is not connected to the control gate line CG. In addition, the gate electrode of the transistor Tr2 is connected to the bit line BL via the capacitor Cap and the transistor Tr3.

### [Manufacturing Method]

A manufacturing method of the semiconductor memory device according to the fourth embodiment is basically similar to the manufacturing method of the semiconductor memory device according to the first embodiment. However, in the manufacturing method of the semiconductor memory device according to the fourth embodiment, the opening 150A is not formed. In addition, the processes described with reference to FIG. 31 to FIG. 34 are not executed in the process described with reference to FIGS. 13 and 14.

### [Operation]

A read operation, a write operation, a data inversion operation, and a self-refresh operation of the semiconductor memory device according to the fourth embodiment are executable similarly to the semiconductor memory device according to the first embodiment.

### [Effect]

The semiconductor memory device according to the fourth embodiment does not include the electrode 150 and the insulating layer 151. Therefore, compared with the semiconductor memory device according to the first embodiment, high integration is easily achievable.

### Fifth Embodiment

### [Configuration]

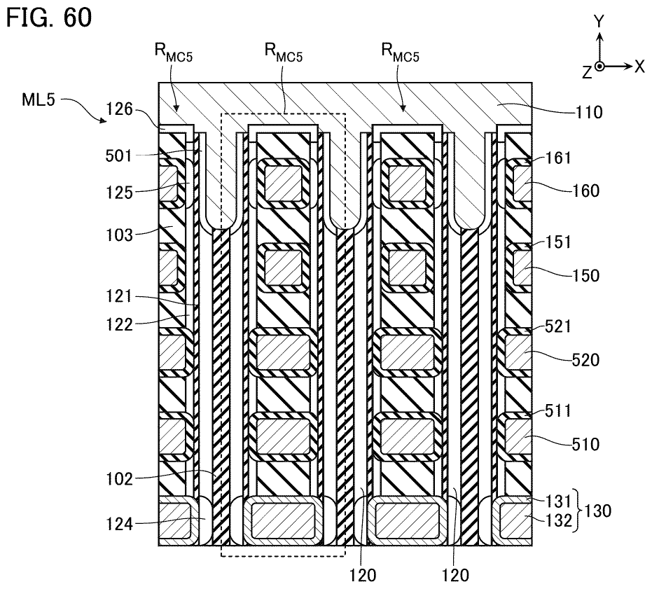

FIG. 60 is a schematic plan view illustrating a part of a configuration of a semiconductor memory device according to the fifth embodiment.

The semiconductor memory device according to the fifth embodiment is basically configured similarly to the semiconductor memory device according to the first embodiment. However, the semiconductor memory device according to the fifth embodiment includes a memory layer ML5, instead of the memory layer ML.

As illustrated in in FIG. 60, the memory layer ML5 includes a plurality of memory cell regions R_{MC5} arranged in the X direction and the conductive layer 110 extending in the X direction along the plurality of memory cell regions R_{MC5}. Between two memory cell regions R_{MC5} mutually adjacent in the X direction, the insulating layer 102 of silicon nitride (Si₃N₄) or the like is disposed.

The structure in the memory cell region RMCs is basically similar to the structure in the memory cell region R_{MC}.

However, between two semiconductor layers 120 of the memory cell region R_{MC5}, five electrodes 130, 510, 520, 150, and 160 arranged in the Y direction are disposed. The electrode 510 is closer to the conductive layer 110 than the electrode 130. The electrode 520 is closer to the conductive layer 110 than the electrode 510. The electrode 150 is closer to the conductive layer 110 than the electrode 520. The electrodes 510 and 520 penetrate a plurality of the memory layers ML5 to extend in the z direction. Insulating layers 511 and 521 are disposed on outer peripheral surfaces of the electrode 510 and 520, respectively.

The electrodes 510 and 520 are configured similarly to the electrode 140 of the semiconductor memory device according to the first embodiment. Furthermore, the insulating layers 511 and 521 are configured similarly to the insulating layer 141 of the semiconductor memory device according to the first embodiment.

In the memory cell region R_{MC5}, at a connecting portion to the conductive layer 110 of the semiconductor layer 120, an impurity region 501 is disposed. The impurity region 501 contains, for example, P-type impurities such as boron (B).

### [Manufacturing Method]

A manufacturing method of the semiconductor memory device according to the fifth embodiment is basically similar to the manufacturing method of the semiconductor memory device according to the first embodiment. However, in the manufacturing method of the semiconductor memory device according to the fifth embodiment, the openings 150A are formed at the positions corresponding to the electrodes 510 and 520 in the process described with reference to FIGS. 13 and 14.

### [Read Operation]

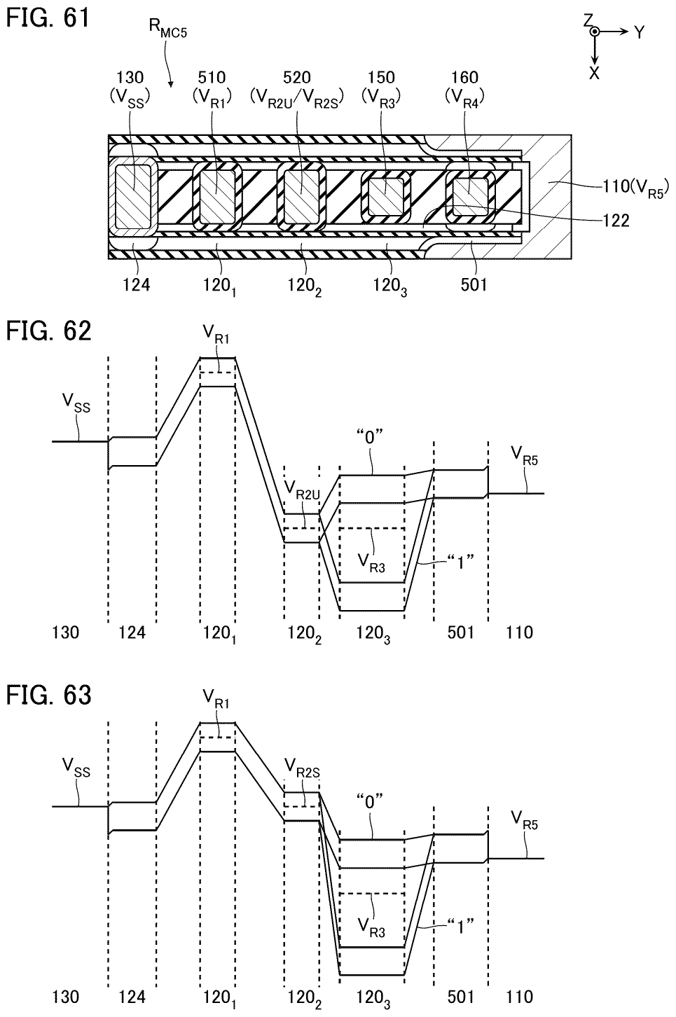

Next, with reference to FIG. 61 to FIG. 63, a read operation of the semiconductor memory device according to the embodiment is described. FIG. 61 is a schematic plan view for describing the read operation. FIGS. 62 and 63 are schematic energy band diagrams for describing the read operation.

In FIG. 61, a region opposed to the electrode 510 of the semiconductor layer 120 is indicated as a region 120₁. A region opposed to the electrode 520 of the semiconductor layer 120 is indicated as a region 120₂. A region opposed to the semiconductor layer 122 of the semiconductor layer 120 is indicated as a region 120₃. In FIGS. 62 and 63, an electric potential at each region in the semiconductor layer 120 is indicated. FIG. 62 corresponds to the semiconductor layer 120 in an unselected memory cell. FIG. 63 corresponds to the semiconductor layer 120 in a selected memory cell.

As illustrated in FIG. 61 to FIG. 63, in the read operation of the semiconductor memory device according to the embodiment, for example, the ground voltage V_{SS} is applied to the electrode 130.

A voltage V_{R1} is applied to the electrode 510. For example, in focusing on the N-channel type field effect transistor where the electrode 510 and the semiconductor layer 120 are set to be the gate electrode and the channel region respectively, a difference between the voltage V_{R1} and the ground voltage V_{SS} is smaller than the threshold voltage of the transistor. Consequently, an electrical potential gradient relative to electrons is formed between the impurity region 124 and the region 120₁ of the semiconductor layer 120, and an electron channel is not formed in the region 120₁.

A voltage V_{R5} is applied to the conductive layer 110. The voltage V_{R5} is larger than the ground voltage V_{SS}.

A voltage V_{R4} is applied to the electrode 160. For example, in focusing on the N-channel type field effect transistor where the electrode 160 and the semiconductor layer 125 are set to be the gate electrode and the channel region respectively, a difference between the voltage V_{R4} and the voltage V_{R5} is smaller than the threshold voltage of the transistor. Consequently, the semiconductor layer 122 is electrically separated from the conductive layer 110.

A voltage V_{R3} is applied to the electrode 150. For example, the P-channel type field effect transistor where the electrode 150 is set to be the gate electrode, and the semiconductor layer 120 is set to be the channel region is focused. In this case, for example, when the data “0” has been stored in the memory cell, a difference between the voltage V_{R3} and the voltage V_{R5} is smaller than the threshold voltage of the transistor. Consequently, in a part corresponding to the memory cell where the data “0” has been stored, a hole channel is formed in the region 120₃ of the semiconductor layer 120. On the other hand, for example, when the data “1” is stored in the memory cell, the difference between the voltage V_{R3} and the voltage V_{R5} is larger than the threshold voltage of the transistor. Consequently, in a part corresponding to the memory cell where the data “1” is stored, an electrical potential gradient relative to holes is formed between the impurity region 501 and the region 120₃ of the semiconductor layer 120, and the hole channel is not formed in the region 120₃. Therefore, no current flows through the memory cell where the data “1” has been stored.

A voltage V_{R2U} is applied to the electrode 520 connected to the unselected memory cell. For example, in focusing on the P-channel type field effect transistor where the electrode 520 and the semiconductor layer 120 are set to be the gate electrode and the channel region respectively, a difference between the voltage V_{R2U} and the voltage V_{R5} is larger than the threshold voltage of the transistor. Consequently, in a part corresponding to the unselected memory cell where the data “0” has been stored, an electrical potential gradient relative to the holes is formed between the region 120₃ and the region 120₂ of the semiconductor layer 120, and the hole channel is not formed in the region 120₂. Therefore, no current flows through the unselected memory cell.

A voltage V_{R2S} is applied to the electrode 520 connected to the selected memory cell. For example, in focusing on the P-channel type field effect transistor where the electrode 520, and the semiconductor layer 120 are set to be the gate electrode and the channel region respectively, a difference between the voltage V_{R2S} and the voltage V_{R5} is smaller than the threshold voltage of the transistor. Consequently, in a part corresponding to the selected memory cell where the data “0” has been stored, the hole channel is formed in the regions 120₃ and 120₂ of the semiconductor layer 120. Thus, the holes supplied from the conductive layer 110 reach the region 120₁ via the impurity region 501 and the regions 120₃ and 120₂ to be accumulated. The accumulated holes raise the electric potential of the region 120₁, and thus, the electrons flow from the electrode 130 into the region 120₃ to lower the electric potential of the region 120₃. In this way, the holes and the electrons perform a positive feedback operation lowering a barrier one another, and thus, finally, the whole semiconductor layer 120 operates as a PIN diode in a forward bias. Therefore, the current flows through the selected memory cell where the data “0” has been stored.

In addition, before execution of the read operation, to the electrode 130, a voltage larger than the ground voltage V_{SS} may be applied. Thus, electric charge accumulated in the semiconductor layer 120 can be discharged to ensure high accuracy of the read operation.

### [Write Operation]

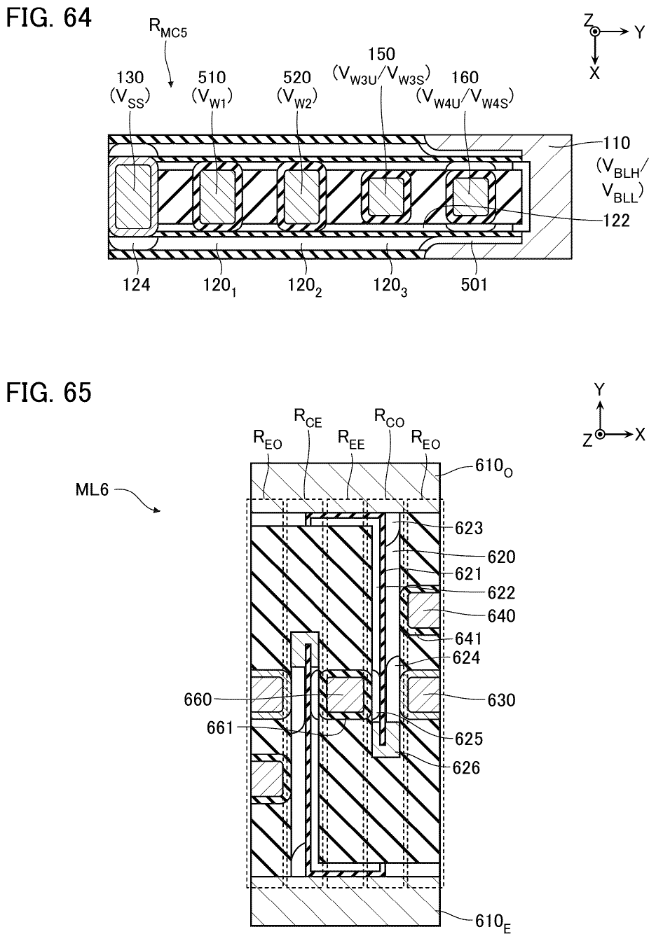

Next, with reference to FIG. 64, a write operation of the semiconductor memory device according to the embodiment is described. FIG. 64 is a schematic plan view for describing the write operation.

As illustrated in FIG. 64, in the write operation of the semiconductor memory device according to the embodiment, for example, a voltage V_{W1} is applied to the electrode 510. For example, in focusing on the N-channel type field effect transistor where the electrode 510 is set to be the gate electrode, the voltage V_{W1} is smaller than the threshold voltage of the transistor. Consequently, the electrical potential gradient relative to the electrons is formed between the impurity region 124 and the region 120₁ of the semiconductor layer 120, no electron channel is formed in the region 120₁.

Furthermore, in storing the data “1” in the selected memory cell, the voltage V_{BLH} is applied to the conductive layer 110. In storing the data “0” in the selected memory cell, the voltage V_{BLL} is applied to the conductive layer 110.

A voltage V_{W4S} is applied to the electrode 160 connected to the selected memory cell. For example, in focusing on the N-channel type field effect transistor where the electrode 160 is set to be the gate electrode, differences between the voltage V_{W4S} and the voltages V_{BLH} and V_{BLL} are larger than the threshold voltage of the transistor. Consequently, the semiconductor layer 122 is electrically conducted with the conductive layer 110.

Voltages V_{W4U} are applied to the other electrodes 160. For example, in focusing on the N-channel type field effect transistor where the electrode 160 is set to be the gate electrode, differences between the voltage V_{W4U} and the voltages V_{BLH} and V_{BLL} are smaller than the threshold voltage of the transistor. Consequently, the semiconductor layer 122 is electrically separated from the conductive layer 110.

A voltage V_{W3S} is applied to the electrode 150 connected to the selected memory cell. For example, the voltage V_{W3S} may be a voltage having a magnitude approximately the same as the voltage V_{BLL} and may be a voltage larger than the voltage V_{BLL} and smaller than the voltage V_{BLH}. In association with this, when the voltage V_{BLH} is applied to the conductive layer 110, positive electric charge is accumulated in a capacitor where the electrode 150 is set to be one electrode and the semiconductor layer 122 is set to be the other electrode. On the other hand, when the voltage V_{BLL} is applied to the conductive layer 110, no electric charge is accumulated, or negative electric charge is accumulated in the capacitor.

Voltage V_{W3U} are applied to the other electrodes 150. The voltage V_{W3U} may be, for example, a voltage having a magnitude approximately the same as the voltage V_{BLL} or may be a voltage having a magnitude approximately the same as the voltage V_{BLH}.

A voltage V_{W2} is applied to the electrode 520. For example, in focusing the P-channel type field effect transistor where the electrode 520 is set to be the gate electrode, differences between the voltage V_{W2} and the voltages V_{BLH} and V_{BLL} are larger than the threshold voltage of the transistor. Consequently, the electrical potential gradient relative to the holes is formed between the impurity region 124 and the region 120₁ of the semiconductor layer 120, no hole channel is formed in the region 120₁.

### [Effect]

In the semiconductor memory device according to the first embodiment, a part of the semiconductor layer 120 (the impurity region 123 in the example in FIG. 2) is opposed to the semiconductor layer 125 via the insulating layer 121. In such configuration, the electron channel is formed in the semiconductor layer 125 at a timing when the voltage is applied to the semiconductor layer 120 in the read operation, and electric charge in the semiconductor layer 122 is sometimes discharged. Thus, the data stored in the memory cell MC (FIG. 3) is sometimes corrupted.

In order to reduce such phenomenon, for example, it is conceivable that the electric potential of the semiconductor layer 122 during the read operation is raised to increase an energy barrier between the semiconductor layer 122 and the semiconductor layer 125 by adjusting an impurity concentration in the semiconductor layer 122 or raising the voltage of the electrode 150 during the read operation. However, when the electric potential of the semiconductor layer 122 during the read operation is raised, the N-channel type field effect transistor (the transistor Tr2 in FIG. 3) where the region 120₃ of the semiconductor layer 120 is set to be the channel region easily turns ON. In such case, in a selected memory cell MC where the data “0” has been stored, a leakage current is possibly generated. In order to reduce such leakage current, for example, it is conceivable that the threshold voltage of the N-channel type field effect transistor (the transistor Tr2 in FIG. 3) is increased by doping P-type impurities such as boron (B) into the semiconductor layer 120 and relatively increasing a concentration of the impurities. However, in such case, the current flowing in the selected memory cell where the data “1” has been stored decreases, and determination of the data possibly becomes difficult.

Thus, in the semiconductor memory device according to the fifth embodiment, as described with reference to FIG. 60, the conductive layer 110 is connected to the semiconductor layer 120 via the impurity region 501 containing the P-type impurities, and the electrode 130 is connected to the semiconductor layer 120 via the impurity region 124 containing the N-type impurities. Furthermore, the two electrodes 510 and 520 are arranged between the electrodes 130 and 150. In such configuration, a positive feedback operation where an electron current and a hole current amplify with one other occurs in the selected memory cell during the read operation. Thus, it is possible to flow the relatively large current to the selected memory cell. It is possible to preferably reduce the leakage current in an unselected memory cell by preferably/appropriately adjusting the electric potentials of the regions 120₁ and 120₂ of the semiconductor layer 120 by the two electrodes 510 and 520. Therefore, the semiconductor memory device that can easily determine the data of the selected memory cell to preferably operate can be achieved.

### Sixth Embodiment

### [Configuration]

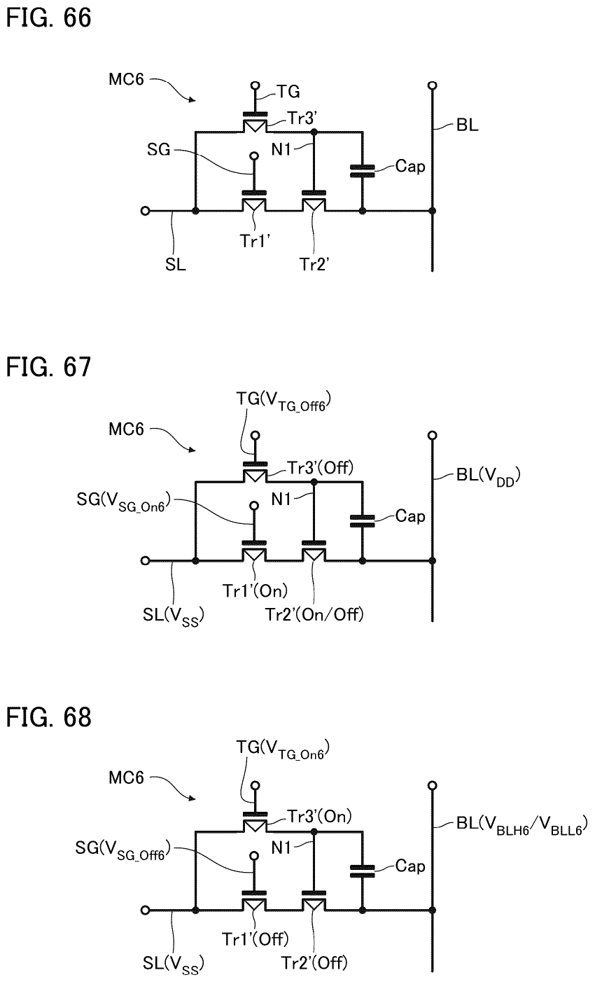

FIG. 65 is a schematic plan view illustrating a part of a configuration of a semiconductor memory device according to the sixth embodiment. FIG. 66 is a schematic circuit diagram illustrating a part of the configuration of the semiconductor memory device according to the embodiment.

The semiconductor memory device according to the sixth embodiment is basically configured similarly to the semiconductor memory device according to the first embodiment. However, the semiconductor memory device according to the sixth embodiment includes a memory layer ML6 instead of the memory layer ML.

As illustrated in FIG. 65, the memory layer ML6 includes a pair of conductive layers 6100 and 610€ extending in the X direction and arranged in the Y direction. The memory layer ML6 includes a plurality of channel semiconductor regions R_{CE} and R_{CO} alternately arranged in the X direction in the region between them. Between the two channel semiconductor regions R_{CE} and R_{CO} mutually adjacent in the X direction, an electrode region R_{EO} or an electrode region R_{EE} is disposed. The electrode regions R_{EO} and R_{EE} are alternately arranged in the X direction.

In the channel semiconductor region R_{CO}, the memory layer ML6 includes a semiconductor layer 620 extending in the Y direction. The memory layer ML6 includes an insulating layer 621 disposed on a side surface in the X direction of the semiconductor layer 620 and a semiconductor layer 622 disposed on a side surface in the X direction of the insulating layer 621. The semiconductor layer 620 has one end portion in the Y direction where an impurity region 623 is disposed. The semiconductor layer 620 is connected to the conductive layer 6100 via the impurity region 623. The semiconductor layer 620 has the other end portion in the Y direction where an impurity region 624 is disposed. The semiconductor layer 622 has one end portion in the Y direction insulated from the semiconductor layer 620 via the insulating layer 621. The semiconductor layer 622 has the other end portion in the Y direction where a semiconductor layer 625 is disposed. At the other end portions of the semiconductor layers 620 and 622, a conductive layer 626 connected to them is disposed. The semiconductor layer 620 is connected to the conductive layer 626 via the impurity region 624. The semiconductor layer 622 is connected to the conductive layer 626 via the semiconductor layer 625.

The configuration of the memory layer ML6 in the channel semiconductor region R_{CE} is basically similar to the configuration of the memory layer ML6 in the channel semiconductor region R_{CO}. However, the semiconductor layer 620 in the channel semiconductor region R_{CE} is connected to the conductive layer 610_{E}, not to the conductive layer 6100.

In the electrode region R_{EO}, two electrodes 630 and 640 arranged in the Y direction are disposed. On an outer peripheral surface of the electrode 640, an insulating layer 641 is disposed. The electrode 630 is connected to the impurity region 624 of the semiconductor layer 620. The electrode 640 is opposed to semiconductor layer 620 via the insulating layer 641. The electrodes 630 and 640 penetrate a plurality of the memory layers ML6 and extend in the Z direction.

In the electrode region R_{EE}, an electrode 660 is disposed. On an outer peripheral surface of the electrode 660, an insulating layer 661 is disposed. The electrode 660 is opposed to two semiconductor layers 625 arranged in the X direction, via the insulating layer 661. In the X direction, the electrode 660 is arranged with the electrode 630, the impurity region 624 of the semiconductor layer 620, and the semiconductor layer 625. The electrode 660 penetrates the plurality of memory layers ML6 and extends in the Z direction.

The conductive layers 6100 and 610; are configured similarly to the conductive layer 110. The semiconductor layer 620 is basically configured similarly to the semiconductor layer 120. However, the impurity regions 623 and 624 of the semiconductor layer 620 may contain N-type impurities such as phosphorus (P) or may contain P-type impurities such as boron (B). The insulating layer 621 is configured similarly to the insulating layer 121. The semiconductor layer 622 is configured similarly to the semiconductor layer 122. The semiconductor layer 625 is configured similarly to the semiconductor layer 125. The electrodes 630, 640, and 660 are configured similarly to the electrodes 130, 140, and 160. The insulating layers 641 and 661 are configured similarly to the insulating layers 141 and 161.

Each configuration in the channel semiconductor region R_{CE} or the channel semiconductor region R_{CO} and each configuration in the pair of electrode regions R_{EO} and R_{EE} mutually adjacent to them configure a memory cell MC6 as illustrated in FIG. 66. The memory cell MC6 includes the transistor Tr1′ and Tr2′ connected in series between the bit line BL and the source line SL. A gate electrode of the transistor Tr1′ is connected to the select gate line SG. The memory cell MC6 includes the node N1 connected to a gate electrode of the transistor Tr2′, the transistor Tr3′ connected between the node N1 and the source line SL, and the capacitor Cap connected between the node N1 and the bit line BL. A gate electrode of the transistor Tr3′ is connected to the transfer gate line TG.

### [Read Operation]

Next, with reference to FIG. 67, a read operation of the semiconductor memory device according to the embodiment is described. FIG. 67 is a schematic circuit diagram for describing the read operation.

In the read operation of the semiconductor memory device according to the embodiment, the voltage V_{DD} is applied to the bit line BL.

When positive electric charge has been accumulated in the node N1, the transistor Tr2′ turns OFF. On the other hand, when no electric charge has been accumulated in the node N1, the transistor Tr2′ turns ON.

A voltage V_{SG_On6} is applied to the select gate line SG connected to a selected memory cell MC6. A difference between the voltage V_{SG_On6} and the voltage V_{DD} is smaller than the threshold voltage of the transistor Tr1′. Thus, the transistor Tr1′ in the selected memory cell MC6 turns ON.

Voltage V_{SG_Off6} are applied to the other select gate lines SG. A difference between the voltage V_{SG_Off6} and the voltage V_{DD} is larger than the threshold voltage of the transistor Tr1′. Thus, the transistor Tr1′ in an unselected memory cell MC6 turns OFF.

The ground voltage V_{SS} is applied to the source line SL.

A voltage V_{TG_Off6} is applied to the transfer gate line TG. A difference between the voltage V_{TG_Off6} and the ground voltage V_{SS} is larger than the threshold voltage of the transistor Tr3′. Thus, the transistor Tr3 turns OFF.

### [Write Operation]

Next, with reference to FIG. 68, the write operation of the semiconductor memory device according to the embodiment is described. FIG. 68 is a schematic circuit diagram for describing the write operation.

In the write operation of the semiconductor memory device according to the embodiment, in storing the data “1” in the memory cell MC6, a voltage V_{BLL6} is applied to the bit line BL. On the other hand, in storing the data “0” in the memory cell MC6, a voltage V_{BLH6} is applied to the bit line BL. The voltage V_{BLL6} is, for example, smaller than the voltage V_{BLH6}.

The voltage V_{SG_Off6} is applied to the select gate line SG to turn OFF the transistor Tr1′.

The ground voltage V_{SS} is applied to the source line SL.

A voltage V_{TG_On6} is applied to the transfer gate line TG connected to the selected memory cell MC6. A difference between the voltage V_{TG_On6} and the ground voltage V_{SS} is smaller than the threshold voltage of the transistor Tr3′. Thus, the transistor Tr3′ in the selected memory cell MC6 turns ON.

The voltages V_{TG_Off6} are applied to the other transfer gate lines TG to turn OFF the transistor Tr3′ in an unselected memory cell MC6.

Here, when the voltage V_{BLL6} has been applied to the bit line BL, electric charge is accumulated in the capacitor Cap between the node N1 and the bit line BL (between the semiconductor layers 620 and 622 in FIG. 65). On the other hand, when the voltage V_{BLH6} has been applied to the bit line BL, no electric charge is accumulated in the capacitor Cap, or electric charge of the reversed polarity is accumulated in the capacitor Cap.

### [Effect]

As described above, in the semiconductor memory device (FIG. 2) according to the first embodiment, the electron channel is formed in the semiconductor layer 125 at the timing when the voltage is applied to the semiconductor layer 120 in the read operation, and the data stored in the memory cell is sometimes corrupted.

Thus, in the semiconductor memory device according to the sixth embodiment, as described with reference to FIG. 65, the side surface of one side in the X direction of the semiconductor layer 625 is opposed to the electrode 660, and the side surface of the other side in the X direction of the semiconductor layer 625 is opposed to the impurity region 624 of the semiconductor layer 620. In such configuration, for example, by applying the ground voltage V_{SS} to the electrode 660 in the read operation, the formation of the channel in the semiconductor layer 625 can be reduced in the read operation. Therefore, the semiconductor memory device that preferably operates can be achieved.

### [Others]

The semiconductor memory devices according to the first embodiment to the sixth embodiment have been described above. However, these configurations are merely examples, and the specific configuration is adjustable, as necessary.

For example, the semiconductor memory device according to the third embodiment may include the impurity region 126 similar to the first embodiment, instead of the impurity region 226 similar to the second embodiment.

Furthermore, for example, the semiconductor memory device according to the fourth embodiment may include the impurity region 226 similar to the second embodiment, instead of the impurity region 126 similar to the first embodiment. The semiconductor memory device according to the fourth embodiment may include the impurity regions 323 and 324 similar to the third embodiment, instead of the impurity regions 123 and 124 similar to the first embodiment.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a bit line;
a source line;
a first transistor and a second transistor connected in series between the bit line and the source line;
a first wiring connected to a gate electrode of the second transistor;
a third transistor connected between the first wiring and the bit line;
a capacitor connected to the first wiring;
a first signal line connected to a gate electrode of the first transistor;
a second signal line connected to the capacitor; and
a third signal line connected to a gate electrode of the third transistor, wherein
at a first timing:
a first voltage is applied to the bit line,
a second voltage is applied to the first signal line,
a third voltage is applied to the second signal line, and
a fourth voltage is applied to the third signal line,
at a second timing:
a fifth voltage different from the first voltage is applied to the source line,
a sixth voltage larger than the second voltage is applied to the first signal line,
a seventh voltage larger than the third voltage is applied to the second signal line, and
the fourth voltage is applied to the third signal line, and
at a third timing:
the second voltage is applied to the first signal line,
the third voltage is applied to the second signal line, and
an eighth voltage larger than the fourth voltage is applied to the third signal line, wherein
the fifth voltage is smaller than the first voltage.
